(19) United States
(12) Patent Application Publication
(10) Pub. No.: US 2023/0422643 A1
(43) Pub. Date: Dec. 28, 2023

(54) RADIO FREQUENCY SWITCH FOR MULTI-BAND FILTER APPLICATIONS AND METHODS FOR FORMING THE SAME

(71) Applicant: Taiwan Semiconductor Manufacturing Company Limited, Hsinchu (TW)

(72) Inventors: Kuo-Pin Chang, Hsinchu (TW); Yu-Wei Ting, Taipei City (TW); Kuo-Ching Huang, Hsinchu City (TW)

(21) Appl. No.: 17/851,072

(22) Filed: Jun. 28, 2022

(51) Int. Cl. H01L 45/00; H01L 27/24

(52) U.S. Cl. CPC H01L 45/1286; H01L 27/2463; H01L 45/1675; H01L 45/06; H01L 45/1226; H01L 45/148; H01L 45/143; H01L 45/144

(57) ABSTRACT

A semiconductor structure comprising a first electrode, a second electrode, a phase-change material (PCM) line in contact with and positioned between the first electrode and the second electrode, at least two heater lines positioned between the first electrode and the second electrode, and an isolation layer positioned between the PCM line and the at least two heater lines is provided. A method of forming a semiconductor structure is provided, the method including forming a dielectric isolation layer having a planar top surface over a substrate, forming at least two heater lines over the planar top surface, forming at least one heater-capping dielectric plate over the at least two heater lines, forming a phase-change material (PCM) line over the at least one heater-capping dielectric plate, forming a first electrode and a second electrode, and forming a PCM-capping dielectric plate over the PCM line.

### BACKGROUND

Phase-change material switches are useful devices that are immune to interference by electromagnetic radiation, and may be used for various applications such as radio-frequency applications. However, phase-change material switches consume significant chip package space, and are limited in functionality due to their on/off state binary nature.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first exemplary structure after formation of complementary metal-oxide-semiconductor (CMOS) transistors, metal interconnect structures and dielectric material layers, an optional dielectric capping layer, a dielectric isolation layer, a metallic material layer, and a dielectric capping material layer, and a sacrificial material layer according to a first embodiment of the present disclosure.

FIGS. 2A-2C are various views of the first exemplary structure after formation of sacrificial capping plates, heater-capping dielectric plates, and heater lines according to a first embodiment of the present disclosure. FIG. 2A is a top-down view, and FIGS. 2B and 2C are vertical cross-sectional views along the vertical plane B-B′ or C-C′ of FIG. 2A, respectively.

FIGS. 3A-3C are various views of the first exemplary structure after formation of an insulating matrix layer according to the first embodiment of the present disclosure. FIG. 3A is a top-down view, and FIGS. 3B and 3C are vertical cross-sectional views along the vertical plane B-B′ or C-C′ of FIG. 3A, respectively.

FIGS. 4A-4C are various views of the first exemplary structure after formation of a phase-change material (PCM) layer and a sacrificial cover material layer according to the first embodiment of the present disclosure. FIG. 4A is a top-down view, and FIGS. 4B and 4C are vertical cross-sectional views along the vertical plane B-B′ or C-C′ of FIG. 4A, respectively.

FIGS. 5A-5C are various views of the first exemplary structure after formation of a PCM line according to the first embodiment of the present disclosure. FIG. 5A is a top-down view, and FIGS. 5B and 5C are vertical cross-sectional views along the vertical plane B-B′ or C-C′ of FIG. 5A, respectively.

FIGS. 6A-6C are various views of the first exemplary structure after formation of a metallic material layer and a sacrificial material layer according to a first embodiment of the present disclosure. FIG. 6A is a top-down view, and FIGS. 6B and 6C are vertical cross-sectional views along the vertical plane B-B′ or C-C′ of FIG. 6A, respectively.

FIGS. 7A-7C are various views of the first exemplary structure after formation of electrodes according to the first embodiment of the present disclosure. FIG. 7A is a top-down view, and FIGS. 7B and 7C are vertical cross-sectional views along the vertical plane B-B′ or C-C′ of FIG. 7A, respectively.

FIGS. 8A-8C are various views of the first exemplary structure after formation of a PCM-capping dielectric layer and a sacrificial cover material layer according to a first embodiment of the present disclosure. FIG. 8A is a top-down view, and FIGS. 8B and 8C are vertical cross-sectional views along the vertical plane B-B′ or C-C′ of FIG. 8A, respectively.

FIGS. 9A-9C are various views of the first exemplary structure after formation of a PCM-capping dielectric plate according to the first embodiment of the present disclosure. FIG. 9A is a top-down view, and FIGS. 9B and 9C are vertical cross-sectional views along the vertical plane B-B′ or C-C′ of FIG. 9A, respectively.

FIGS. 10A-10D are various views of the first exemplary structure after formation of a contact-level dielectric layer and additional metal interconnect structures according to the first embodiment of the present disclosure. FIG. 10A is a top-down view, and FIGS. 10B, 10C, and 10D are vertical cross-sectional views along the vertical plane B-B′, C-C′, or D-D′ of FIG. 10A, respectively.

FIGS. 11A-11D are various views of a first alternative structure including heater lines of various widths according to an embodiment of the present disclosure. FIG. 11A is a top-down view, and FIGS. 11B, 11C, and 11D are vertical cross-sectional views along the vertical plane B-B′, C-C′, or D-D′ of FIG. 11A, respectively.

FIGS. 12A-12D are various views of a second alternative structure including heater lines of various widths according to an embodiment of the present disclosure. FIG. 12A is a top-down view, and FIGS. 12B, 12C, and 12D are vertical cross-sectional views along the vertical plane B-B′, C-C′, or D-D′ of FIG. 12A, respectively.

FIGS. 13A-13D are various views of a third alternative structure including heater lines of various materials according to an embodiment of the present disclosure. FIG. 13A is a top-down view, and FIGS. 13B, 13C, and 13D are vertical cross-sectional views along the vertical plane B-B′, C-C′, or D-D′ of FIG. 13A, respectively.

FIGS. 14A-14D are various views of a fourth alternative structure including a single heater-capping dielectric plate formed over multiple heater lines according to an embodiment of the present disclosure. FIG. 14A is a top-down view, and FIGS. 14B, 14C, and 14D are vertical cross-sectional views along the vertical plane B-B′, C-C′, or D-D′ of FIG. 14A, respectively.

FIG. 15 is a top-down view of a fifth alternative structure including two PCM lines and multiple heater lines according to an embodiment of the present disclosure.

FIGS. 16A-16D are various views of a sixth alternative structure including multiple heater lines according to an embodiment of the present disclosure. FIG. 16A is a top-down view, and FIGS. 16B, 16C, and 16D are vertical cross-sectional views along the vertical plane B-B′, C-C′, or D-D′ of FIG. 16A, respectively.

FIGS. 17A-17D are various views of a seventh alternative structure including multiple trench heater lines according to an embodiment of the present disclosure. FIG. 17A is a top-down view, and FIGS. 17B, 17C, and 17D are vertical cross-sectional views along the vertical plane B-B′, C-C′, or D-D′ of FIG. 17A, respectively.

FIGS. 18A-18E are various views of an eighth alternative structure including multiple heater lines and a trench heater line according to an embodiment of the present disclosure. FIG. 18A is a top-down view, and FIGS. 18B, 18C, 18D and 18E are vertical cross-sectional views along the vertical plane B-B′, C-C′, D-D′ or E-E′ of FIG. 18A, respectively.

FIG. 19 is a first flowchart that illustrates the general processing steps for manufacturing the semiconductor devices according to some embodiments of the present disclosure.

FIG. 20 is a second flowchart that illustrates the general processing steps for manufacturing the semiconductor devices according to some embodiments of the present disclosure.

FIG. 21 is a third flowchart that illustrates the general processing steps for manufacturing the semiconductor devices according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Elements with the same reference numerals refer to the same element, and are presumed to have the same material composition and the same thickness range unless expressly indicated otherwise.

Generally, various embodiment structures and methods are disclosed herein which may be used to form a phase-change material (PCM) switch, which may be used to provide a switching function for various semiconductor devices such as radio-frequency semiconductor devices, varactors (i.e., variable capacitance capacitors), inductors, or other semiconductor devices.

Various embodiments disclosed herein may be directed to semiconductor devices, and particularly to PCM devices including multiple heater lines per PCM line. The various embodiment methods and structures disclosed herein may be used to provide an enhanced chip package structure by reducing the footprint of PCM switches and therefore increasing available space for forming additional semiconductor structures within a chip package.

According to an aspect of the present disclosure, a switch structure including a PCM line and multiple heater lines may be formed. Generally, a heater line, using short pulse width or long pulse width signals, may change the phase state of an PCM line to alter the resistance of the PCM line. Implementing multiple heater lines along the channel length of a single PCM line may allow a PCM line to be configured with more than two resistance states, therefore reducing circuit size (i.e., replacing multiple PCM switches with a single PCM switch) and freeing up space for additional semiconductor structures. A switch implementing a PCM line and multiple heater lines may further provide a larger range of tunable frequencies (e.g., MHz to GHz tunable band pass filter), allowing for an increased and more complex applications. The various embodiment methods and structures disclosed herein are now described with reference to accompanying drawings. In another aspect of the present disclosure, the switch structures may be formed in a back end-of-line (BEOL) process. This provides for additional space savings and may serve different technology nodes.

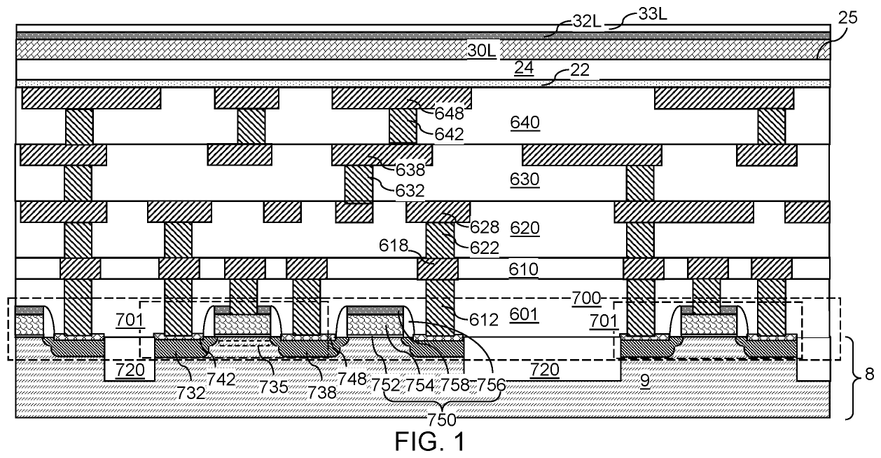

Referring to FIG. 1, a first exemplary structure according to a first embodiment of the present disclosure is illustrated. The first exemplary structure includes a substrate 8, which may be a semiconductor substrate such as a commercially available silicon substrate. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720. Field effect transistors 701 may be formed over the top surface of the semiconductor material layer 9. For example, each field effect transistor 701 may include a source electrode 732, a drain electrode 738, a semiconductor channel 735 that includes a surface portion of the substrate 8 extending between the source electrode 732 and the drain electrode 738, and a gate structure 750. The semiconductor channel 735 may include a single crystalline semiconductor material. Each gate structure 750 may include a gate dielectric layer 752, a gate electrode 754, a gate cap dielectric 758, and a dielectric gate spacer 756. A source-side metal-semiconductor alloy region 742 may be formed on each source electrode 732, and a drain-side metal-semiconductor alloy region 748 may be formed on each drain electrode 738. The devices formed on the top surface of the semiconductor material layer 9 may include complementary metal-oxide-semiconductor (CMOS) transistors and optionally additional semiconductor devices (such as resistors, diodes, capacitor structures, etc.), and are collectively referred to as CMOS circuitry 700.

One or more of the field effect transistors 701 in the CMOS circuitry 700 may include a semiconductor channel 735 that contains a portion of the semiconductor material layer 9 in the substrate 8. If the semiconductor material layer 9 includes a single crystalline semiconductor material such as single crystalline silicon, the semiconductor channel 735 of each field effect transistor 701 in the CMOS circuitry 700 may include a single crystalline semiconductor channel such as a single crystalline silicon channel. In one embodiment, a subset of the field effect transistors 701 in the CMOS circuitry 700 may include a respective node that is subsequently electrically connected to a node of an energy harvesting device and/or to a battery structure to be subsequently formed.

In one embodiment, the substrate 8 may include a single crystalline silicon substrate, and the field effect transistors 701 may include a respective portion of the single crystalline silicon substrate as a semiconducting channel. As used herein, a “semiconducting” element refers to an element having electrical conductivity in the range from 1.0×10-6 S/cm to 1.0×105 S/cm. As used herein, a “semiconductor material” refers to a material having electrical conductivity in the range from 1.0×10-6 S/cm to 1.0×105 S/cm in the absence of electrical dopants therein, and is capable of producing a doped material having electrical conductivity in a range from 1.0 S/cm to 1.0×105 S/cm upon suitable doping with an electrical dopant.

Various metal interconnect structures may be subsequently formed within dielectric material layers over the substrate 8 and the semiconductor devices 701 thereupon (such as field effect transistors). In an illustrative example, the dielectric material layers may include, for example, a first dielectric material layer 601 that may be a layer that surrounds the contact structure connected to the source and drains (sometimes referred to as a contact-level dielectric material layer 601), a first interconnect-level dielectric material layer 610, a second interconnect-level dielectric material layer 620, a third interconnect-level dielectric material layer 630, and a fourth interconnect-level dielectric material layer 640. The metal interconnect structures may include device contact via structures 612 formed in the first dielectric material layer 601 and contact a respective component of the CMOS circuitry 700, first metal line structures 618 formed in the first interconnect-level dielectric material layer 610, first metal via structures 622 formed in a lower portion of the second interconnect-level dielectric material layer 620, second metal line structures 628 formed in an upper portion of the second interconnect-level dielectric material layer 620, second metal via structures 632 formed in a lower portion of the third interconnect-level dielectric material layer 630, third metal line structures 638 formed in an upper portion of the third interconnect-level dielectric material layer 630, third metal via structures 642 formed in a lower portion of the fourth interconnect-level dielectric material layer 640, and fourth metal line structures 648 formed in an upper portion of the fourth interconnect-level dielectric material layer 640. While the present disclosure is described using an embodiment in which four levels metal line structures are formed in dielectric material layers, embodiments are expressly contemplated herein in which a lesser or greater number of levels of metal line structures are formed in dielectric material layers.

Each of the dielectric material layers (601, 610, 620, 630, 640) may include a dielectric material such as undoped silicate glass, a doped silicate glass, organosilicate glass, amorphous fluorinated carbon, porous variants thereof, or combinations thereof. Each of the metal via and interconnect structures (612, 618, 622, 628, 631, 638, 642, 648) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the first metal via structures 622 and the second metal line structures 628 may be formed as integrated line and via structures by a dual damascene process. Generally, any contiguous set of a metal line structure (628, 638, 648) and at least one underlying metal via structure (622, 632, 642) may be formed as an integrated line and via structure.

Generally, semiconductor devices 701 may be formed on a substrate 8, and metal interconnect structures (612, 618, 622, 628, 631, 638, 642, 648) and dielectric material layers (601, 610, 620, 630, 640) may be formed over the semiconductor devices 710. The metal via and interconnect structures (612, 618, 622, 628, 631, 638, 642, 648) may be formed in the dielectric material layers (601, 610, 620, 630, 640), and may be electrically connected to the semiconductor devices 701.

An optional dielectric capping layer 22, a dielectric isolation layer 24, a metallic material layer 30L, a dielectric capping material layer 32L, and an optional sacrificial material layer 33L may be deposited over the metal via and interconnect structures (612, 618, 622, 628, 631, 638, 642, 648) and dielectric material layers (601, 610, 620, 630, 640). The optional dielectric capping layer 22 includes a dielectric capping material such as silicon carbide, silicon nitride, or silicon carbide nitride. The thickness of the optional dielectric capping layer 22, if present, may be in a range from 2 nm to 100 nm, although lesser and greater thicknesses may also be used. The dielectric isolation layer 24 comprises a dielectric material such as undoped silicate glass or a doped silicate glass. The dielectric isolation layer 24 may comprise a planar top surface 25, i.e., a top surface located entirely within a horizontal plane. The thickness of the dielectric isolation layer 24 may be in a range from 100 nm to 300 nm, such as from 120 nm to 200 nm, although lesser and greater thicknesses may also be used.

The metallic material layer 30L includes a metallic material having a lower electrical conductivity than copper or aluminum. The metallic material layer 30L may comprise a refractory elemental metal such as tungsten (W), rhenium (Re), tantalum (Ta), molybdenum (Mo), niobium (Nb), a combination thereof (e.g., tungsten-titanium (TiW), or may comprises a conductive metallic nitride material such as tungsten nitride, titanium nitride, or tantalum nitride. In some embodiments, the metallic material layer 30L may comprise metal such as copper (Cu), aluminum (Al), or gold (Au). The thickness of the metallic material layer 30L may be in a range from 50 nm to 300 nm, such as from 100 nm to 200 nm, although lesser and greater thicknesses may also be used. The dielectric capping material layer 32L comprises a dielectric material such as silicon nitride, silicon carbide, silicon carbide nitride, or a dielectric metal oxide such as aluminum oxide, hafnium oxide, tantalum oxide, yttrium oxide, or lanthanum oxide. The thickness of the dielectric capping material layer 32L may be in a range from 20 nm to 100 nm, such as from 30 nm to 60 nm, although lesser and greater thicknesses may also be used. In some embodiments, an optional sacrificial material layer 33L may be included that comprises a sacrificial material such as silicon oxide. The thickness of the sacrificial material layer 33L may be in a range from 5 nm to 100 nm, such as from 10 nm to 50 nm, although lesser and greater thicknesses may also be used. Generally, a stack including at least a metallic material layer 30L and a dielectric capping material layer 32L may be formed over the planar top surface 25 of the dielectric isolation layer 24.

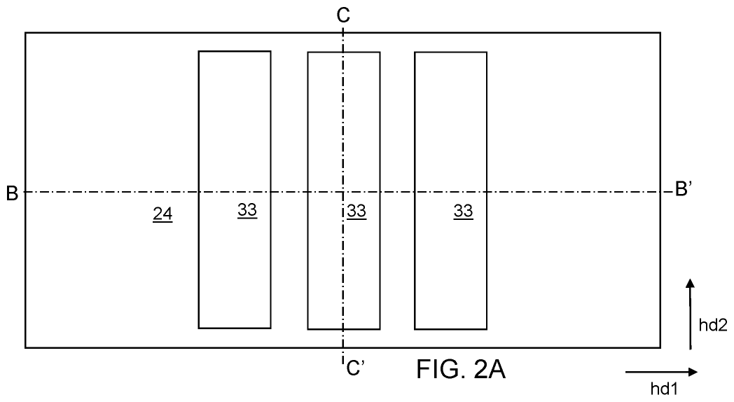

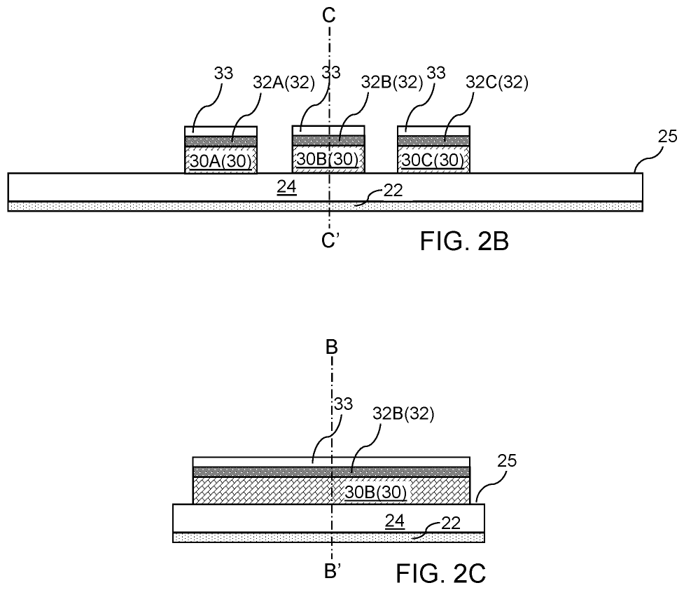

Referring to FIGS. 2A-2C, a photoresist layer (not shown) may be applied over the sacrificial material layer 33L (in embodiments that include the optional sacrificial material layer 33L), and may be lithographically patterned to form discrete photoresist material portions having a respective elongated horizontal cross-sectional shape such as a respective rectangular shape. In one embodiment, the elongated shapes may be rectangular shapes having a respective uniform width along a first horizontal direction hd1 and having a respective length that is greater than the respective uniform width along a second horizontal direction hd2. An anisotropic etch process, such as a reactive ion etch process, may be performed to etch unmasked portions of the sacrificial material layer 33L, the dielectric capping material layer 32L, and the metallic material layer 30L. The anisotropic etch process may be selective to the material of the dielectric isolation layer 24, and the planar top surface 25 of the dielectric isolation layer 24 may be physically exposed in areas that are not masked by the discrete photoresist material portions.

Remaining portions of the sacrificial material layer 33L comprise sacrificial material plates 33. Remaining portions of the metallic material layer 30L comprise a first heater line 30A, a second heater line 30B, and a third heater line 30C. The first heater line 30A, a second heater line 30B, and a third heater line 30C may be collectively referred to as heater lines 30. Remaining portion of the dielectric capping material layer 32L comprise a first heater-capping dielectric plate 32A that contacts a top surface of the first heater line 30A, a second heater-capping dielectric plate 32B that contacts a top surface of the second heater line 30B, and a third heater-capping dielectric plate 32C that contacts a top surface of the third heater line 30C. The first heater-capping dielectric plate 32A, the second heater-capping dielectric plate 32B, and the third heater-capping dielectric plate 32C may be collectively referred to as heater-capping dielectric plates 32.

In one embodiment, the first heater line 30A, the first heater-capping dielectric plate 32A, and a sacrificial material plate 33 that contacts the first heater-capping dielectric plate 32A may have the same area. In one embodiment, the second heater line 30B, the second heater-capping dielectric plate 32B, and a sacrificial material plate 33 that contacts the second heater-capping dielectric plate 32B may have the same area. In one embodiment, the third heater line 30C, the third heater-capping dielectric plate 32C, and a sacrificial material plate 33 that contacts the third heater-capping dielectric plate 32C may have the same area.

In one embodiment, sidewalls of the first heater line 30A, the first heater-capping dielectric plate 32A, and an overlying sacrificial material plate 33 may be vertically coincident, i.e., overlie or underlie one another and are located within a same vertical plane. In one embodiment, sidewalls of the second heater line 30B, the second heater-capping dielectric plate 32B, and an overlying sacrificial material plate 33 may be vertically coincident, i.e., overlie or underlie one another and are located within a same vertical plane. In one embodiment, sidewalls of the third heater line 30C, the third heater-capping dielectric plate 32C, and an overlying sacrificial material plate 33 may be vertically coincident, i.e., overlie or underlie one another and are located within a same vertical plane.

The first heater line 30A contacts a first area of the planar top surface 25, and the first heater-capping dielectric plate 32A contacts the top surface of the first heater line 30A. The second heater line 30B contacts a second area of the planar top surface 25, and the second heater-capping dielectric plate 32B contacts the top surface of the second heater line 30B. The third heater line 30C contacts a third area of the planar top surface 25, and the third heater-capping dielectric plate 32C contacts the top surface of the third heater line 30C.

In some embodiments, the first heater line 30A, the second heater line 30B, and the third heater line 30C may have the same material composition and the same thickness. The first heater-capping dielectric plate 32A, the second heater-capping dielectric plate 32B, and the third heater-capping dielectric plate 32C may have the same material composition and the same thickness. The sacrificial material plates 33 may have the same material composition and the same thickness. The discrete photoresist material portions may be subsequently removed, for example, by ashing.

The first heater line 30A, the second heater line 30B, and the third heater line 30C may have a horizontal cross-sectional shape of a rectangle, and may, or may not, include optional lateral protrusions (not illustrated) in any direction at lengthwise end portions. In some embodiments, the optional lateral protrusions may be advantageously used to increase a contact area between the heater line 30 and heater contact via structures to be subsequently formed. In one embodiment, the first heater line 30A, the second heater line 30B, and the third heater line 30C may be formed on a first area, a second area, and a third area, respectively, of the planar top surface 25 of the dielectric isolation layer 24.

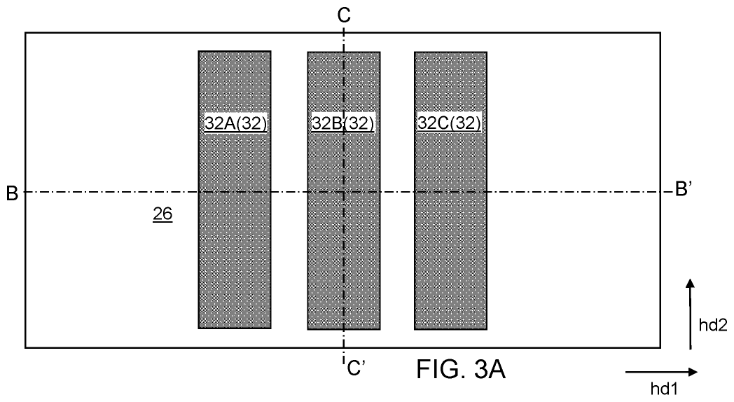

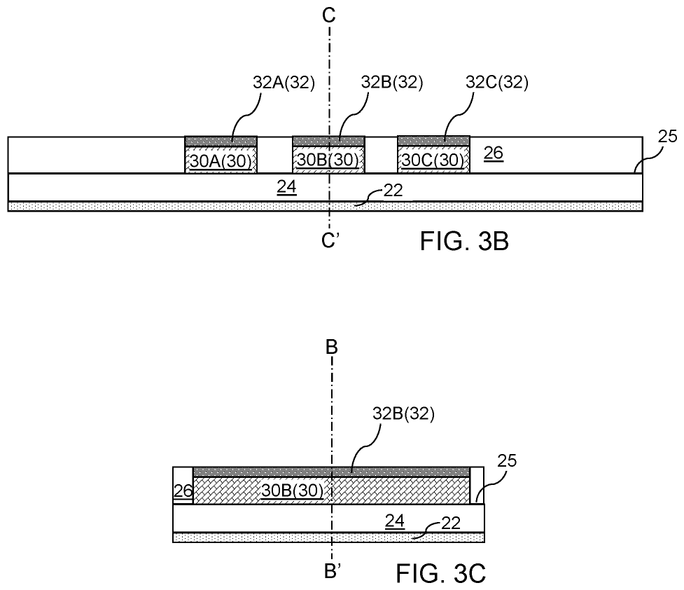

Referring to FIGS. 3A-3C, an insulating material such as undoped silicate glass or a doped silicate glass may be deposited around the heater lines 30. The insulating material may be the same as, or may be different from, the material of the sacrificial material plates 33. A planarization process such as a chemical mechanical polishing (CMP) process may be performed to remove portions of the deposited insulating material that overlie the horizontal plane including the top surfaces of the heater-capping dielectric plates 32. The sacrificial material plates 33 may be collaterally removed during the planarization process. The top surfaces of the heater-capping dielectric plates 32 may be used as planarization stopping surfaces for the planarization process. The remaining portion of the deposited insulating material forms a matrix embedding the heater lines 30, and is herein referred to as an insulating matrix layer 26. The top surface of the insulating matrix layer 26 may be located within the horizontal plane including the top surfaces of the heater-capping dielectric plates 32. The insulating matrix layer 26 is formed around the heater lines 30.

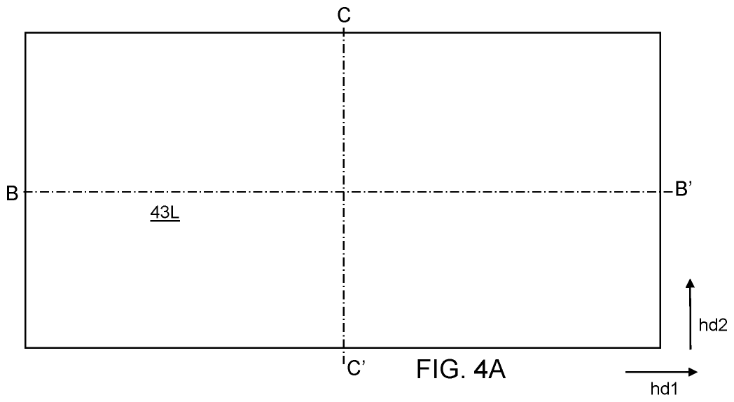

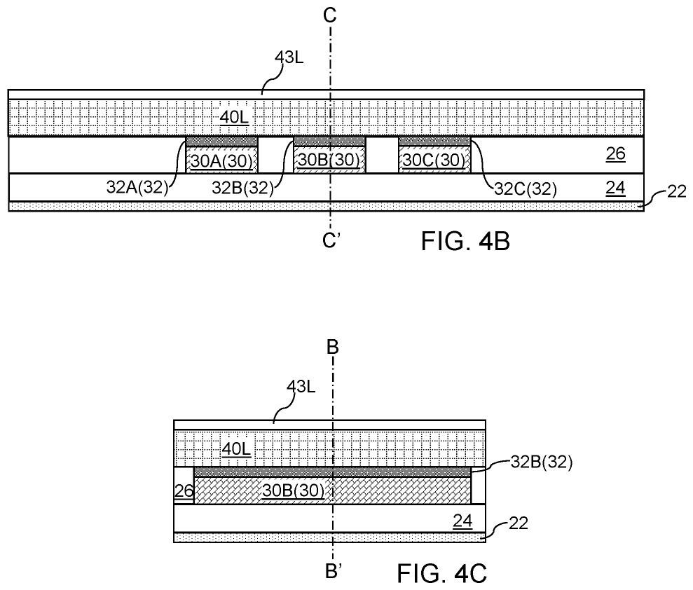

Referring to FIGS. 4A-4C, a phase-change material (PCM) layer 40L and a sacrificial cover material layer 43L may be formed over the heater-capping dielectric plates 32 and the top surface of the insulating matrix layer 26. As used herein, a “phase-change material” may refer to a material having at least two different phases providing different resistivity. A PCM may be used to store information as a resistivity state of a material that may be in different resistivity states corresponding to different phases of the material. The different phases may include an amorphous state having high resistivity and a crystalline state having low resistivity (i.e., a lower resistivity than in the amorphous state). The transition between the amorphous state and the crystalline state may be induced by controlling the rate of cooling after application of an electrical pulse that renders the PCM amorphous in a first part of a programming process. The second part of the programming process includes control of the cooling rate of the PCM. In embodiments in which rapid quenching occurs, the PCM may cool into an amorphous high resistivity state. In embodiments in which slow cooling occurs, the PCM may cool into a crystalline low resistivity state.

Exemplary PCMs include, but are not limited to, germanium antimony telluride (GST) compounds such as Ge2Sb2Te5 or GeSb2Te4, germanium antimony compounds, indium germanium telluride compounds, aluminum selenium telluride compounds, indium selenium telluride compounds, and aluminum indium selenium telluride compounds. The PCM may be doped (e.g., nitrogen doped GST) or undoped to enhance resistance-switching characteristics. The thickness of the PCM layer 40L (which is also referred to as a PCM layer 40L) may be in a range from 30 nm to 600 nm, such as from 60 nm to 300 nm, although lesser and greater thicknesses may also be used.

In some embodiments, an optional sacrificial cover material layer 43L may be included that comprises a sacrificial material such as silicon oxide. The thickness of the sacrificial cover material layer 43L may be in a range from 5 nm to 100 nm, such as from 10 nm to 50 nm, although lesser and greater thicknesses may also be used.

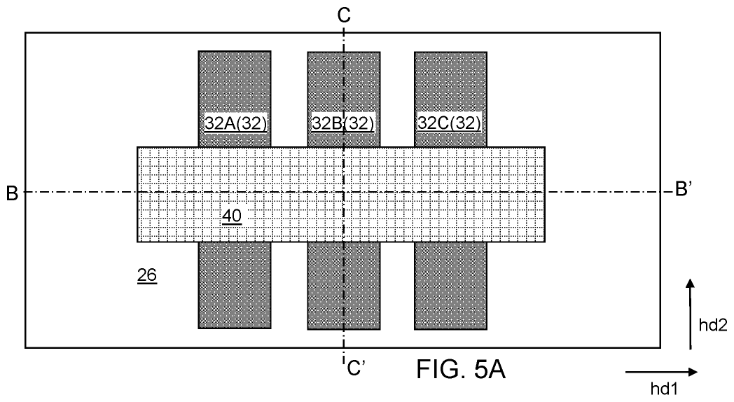

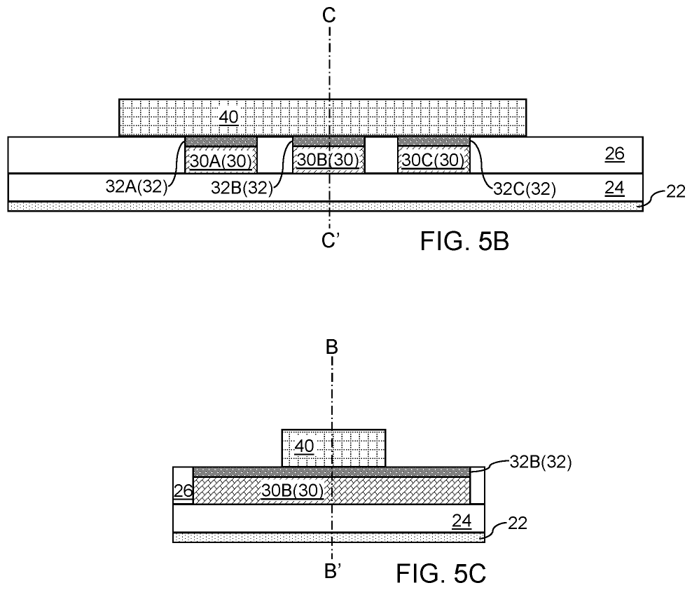

Referring to FIGS. 5A-5C, a photoresist layer (not shown) may be applied over the optional sacrificial cover material layer 43L (in embodiments that include the optional sacrificial cover material layer 43L) and the PCM layer 40L, and may be lithographically patterned to provide an elongated photoresist material portion that straddles the heater-capping dielectric plates 32 (32A-32C), and overlaps with the contact areas between the PCM layer 40L and the heater-capping dielectric plates 32. Unmasked portions of the optional sacrificial cover material layer 43L and the PCM layer 40L may be etched by performing an anisotropic etch process that uses the patterned photoresist material portion as an etch mask. A remaining portion of the PCM layer 40L comprises a PCM line 40, which is also referred to as a PCM line 40. Any remaining portion of the optional sacrificial cover material layer 43L may be removed by performing an etch process (such as an isotropic etch process) that etches the material of the sacrificial cover material layer 43L selective to the materials of the PCM line 40 and the heater-capping dielectric plates 32. For example, a wet etch process using hydrofluoric acid may be used if the sacrificial cover material layer 43L comprises undoped silicate glass or a doped silicate glass.

Generally, the PCM line 40 may be formed over the insulating matrix layer 26. The PCM line 40 may straddle the combination of the heater lines 30 (e.g., 30A-30C) and the heater-capping dielectric plates 32 (e.g., 32A-32C). The heater lines 30 underlie the PCM line 40. The first heater-capping dielectric plate 32A contacts the top surface of the first heater line 30A and contacts a bottom surface of a portion of the PCM line 40. The overlap area of the first heater line 30A and the PCM line 40 in a plan view may be referred to as a first PCM cell. The second heater-capping dielectric plate 32B contacts the top surface of the second heater line 30B and contacts a bottom surface of a portion of the PCM line 40. The overlap area of the second heater line 30B and the PCM line 40 in a plan view may be referred to as a second PCM cell. The third heater-capping dielectric plate 32C contacts the top surface of the third heater line 30C and contacts a bottom surface of a portion of the PCM line 40. The overlap area of the third heater line 30C and the PCM line 40 in a plan view may be referred to as a third PCM cell.

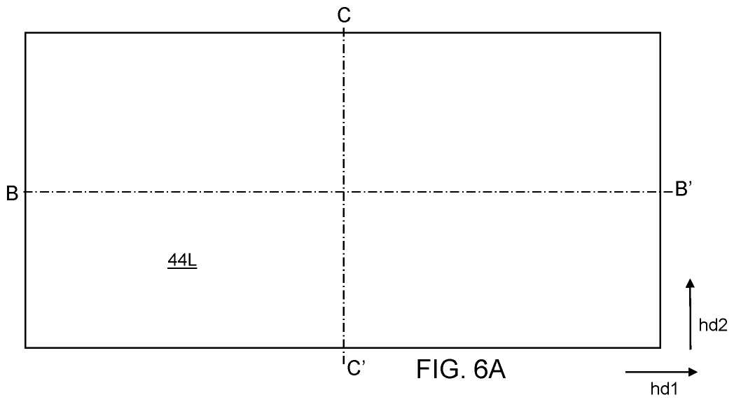

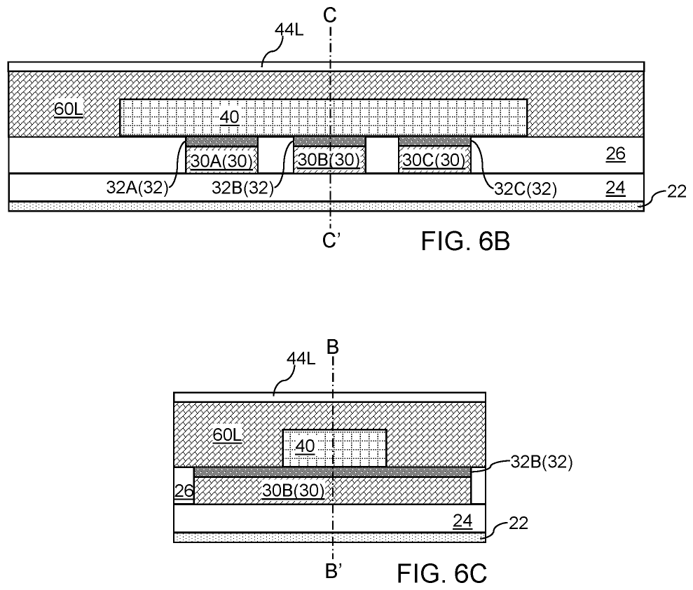

Referring to FIGS. 6A-6C, a metallic material layer 60L and an optional sacrificial material layer 44L may be deposited over the PCM line 40, the heater-capping dielectric plates 32, and the insulating matrix layer 26.

The metallic material layer 60L includes a metallic material having a lower electrical conductivity than copper or aluminum. The metallic material layer 60L may comprise a refractory elemental metal such as tungsten (W), rhenium (Re), tantalum (Ta), molybdenum (Mo), niobium (Nb), a combination thereof (e.g., tungsten-titanium (TiW)), or may comprises a conductive metallic nitride material such as tungsten nitride, titanium nitride, or tantalum nitride. In some embodiments, the metallic material layer 70L may comprise metal such as copper (Cu), aluminum (Al), or gold (Au). The thickness of the metallic material layer 60L may be in a range from 50 nm to 300 nm, such as from 100 nm to 200 nm, although lesser and greater thicknesses may also be used. The optional sacrificial material layer 44L, if present, comprises a sacrificial material such as silicon oxide. The thickness of the sacrificial material layer 44L may be in a range from 5 nm to 100 nm, such as from 10 nm to 50 nm, although lesser and greater thicknesses may also be used.

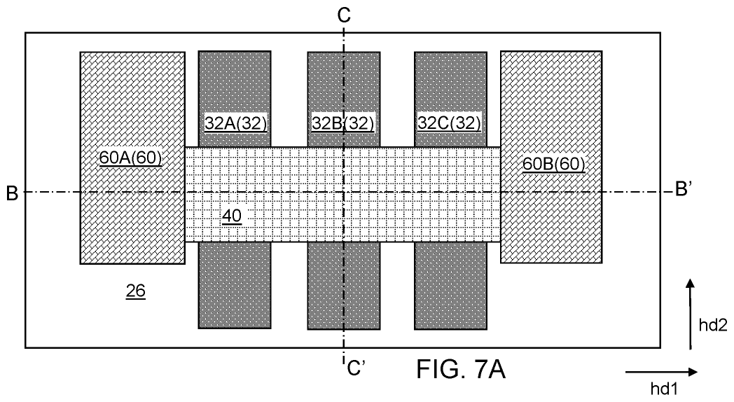

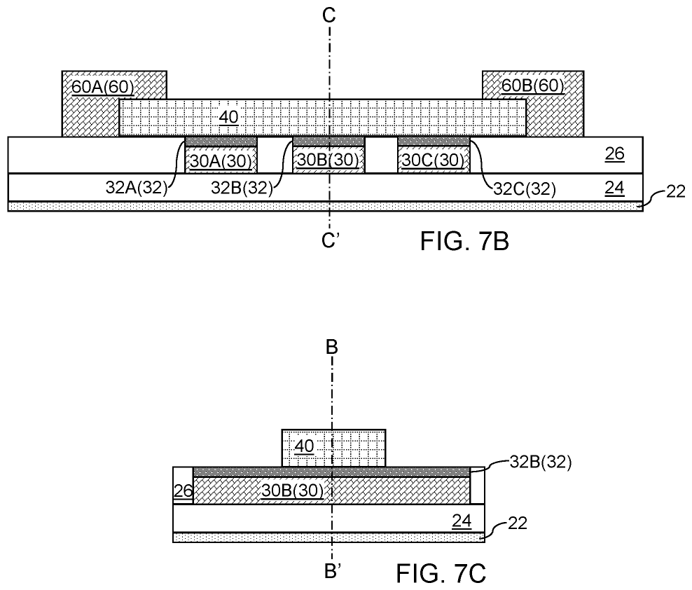

Referring to FIGS. 7A-7C, a photoresist layer (not shown) may be applied over the optional sacrificial material layer 44L (in embodiments that include the optional sacrificial cover material layer 45L) and metallic material layer 60L, and may be lithographically patterned to form discrete photoresist material portions having a respective elongated shape in a plan view such as a respective rectangular shape. In one embodiment, the elongated shapes may be rectangular shapes having a respective uniform width along a first horizontal direction hd1 and having a respective length that is greater than the respective uniform width along a second horizontal direction hd2. An anisotropic etch process, such as a reactive ion etch process, may be performed to etch unmasked portions of the sacrificial material layer 44L and the metallic material layer 60L. The anisotropic etch process may be selective to the material of the insulating matrix layer 26, the PCM line 40, and the heater-capping dielectric plates 32, to expose top surfaces of the insulating matrix layer 26, the PCM line 40, and the heater-capping dielectric plates 32.

Remaining portions of the metallic material layer 60L comprise a first electrode 60A and a second electrode 60B. The first electrode 60A and the second electrode 60B are collectively referred to as electrodes 60. A bottommost surface of the first electrode 60A contacts a top surface of the insulating matrix layer 26, one or more sidewalls of the first electrode 60A contact one or more sidewalls of the PCM line 40, and a bottom surface of the first electrode 60A contacts a topmost surface of the PCM line 40. A bottommost surface of the second electrode 60B contacts a top surface of the insulating matrix layer 26, one or more sidewalls of the second electrode 60B contact one or more sidewalls of the PCM line 40, and a bottom surface of the second electrode 60B contacts a topmost surface of the PCM line 40. A first end portion of the PCM line may be encapsulated by the first electrode 60A, and a second end portion of the PCM line may be encapsulated by the second electrode 60B. In some embodiments, topmost surfaces of the first electrode 60A and the second electrode 60B may be within a same horizontal plane as a topmost surface of the PCM line 40, such that the electrodes 60 are electrically connected the PCM line 40 only through sidewall contact.

In some embodiments, the first electrode 60A may extend over the first heater line 30A in a plan view and may be within a same vertical plan as the first heater line 30A in a cross-sectional view, such that a bottom surface of the first electrode 60A may be in contact with a top surface of the first heater-capping dielectric plate 32A. In some embodiments, the second electrode 60B may extend over the third heater line 30C in a plan view and may be within a same vertical plan as the third heater line 30C in a cross-sectional view, such that a bottom surface of the second electrode 60B may be in contact with a top surface of the third heater-capping dielectric plate 32C.

The first electrode 60A and the second electrode 60B may have the same material composition and the same thickness. The sacrificial material plates 33 may have the same material composition and the same thickness. The discrete photoresist material portions may be subsequently removed, for example, by ashing.

While the first electrode 60A and the second electrode 60B are described in a configuration having a respective rectangular horizontal cross-sectional view and/or plan view shape, embodiments are expressly contemplated in which the first electrode 60A and/or the second electrode 60B have a respective non-rectangular horizontal cross-sectional shape.

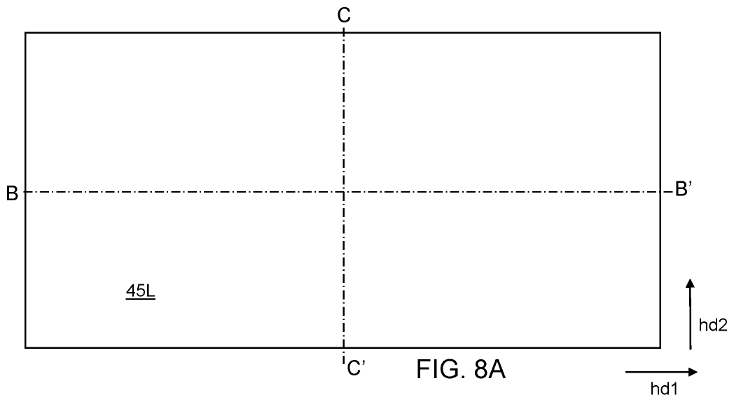

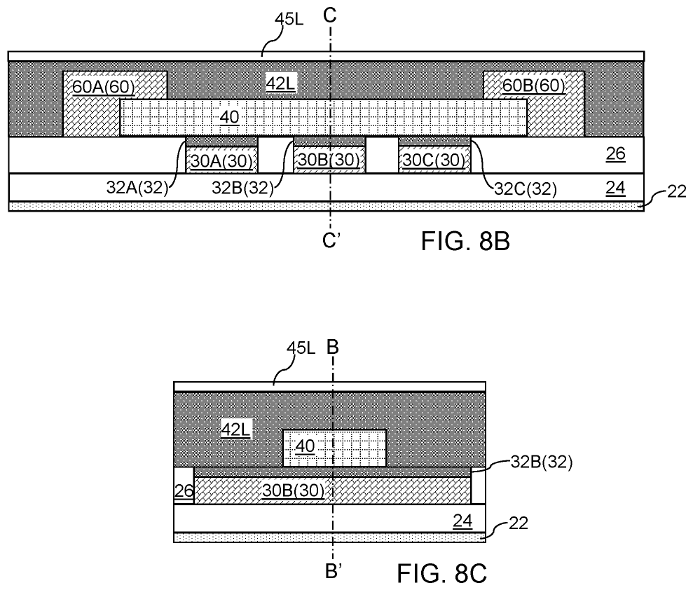

Referring to FIGS. 8A-8C, a PCM-capping dielectric layer 42L and a sacrificial cover material layer 45L may be formed over top surfaces of the first electrode 70A, the second electrode 70B, the PCM line 40, the heater-capping dielectric plates 32, and the insulating matrix layer 26.

The PCM-capping dielectric layer 42L comprises a dielectric material such as silicon nitride, silicon carbide, silicon carbide nitride, or a dielectric metal oxide such as aluminum oxide, hafnium oxide, tantalum oxide, yttrium oxide, or lanthanum oxide. The thickness of the PCM-capping dielectric layer 42L may be in a range from 20 nm to 100 nm, such as from 30 nm to 60 nm, although lesser and greater thicknesses may also be used. In some embodiments, an optional sacrificial cover material layer 45L may be included that comprises a sacrificial material such as silicon oxide. The thickness of the sacrificial cover material layer 45L may be in a range from 5 nm to 100 nm, such as from 10 nm to 50 nm, although lesser and greater thicknesses may also be used.

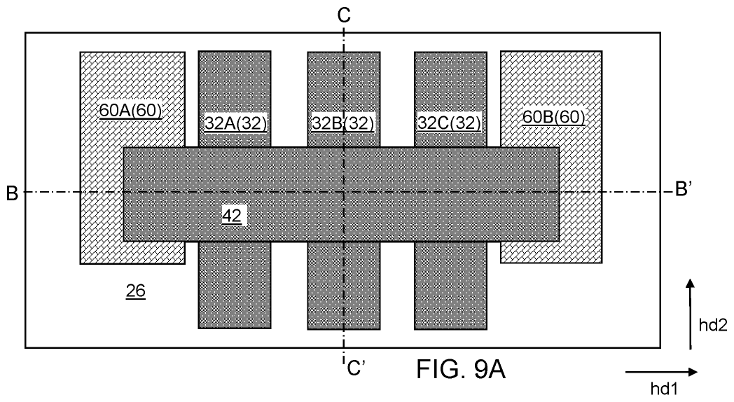

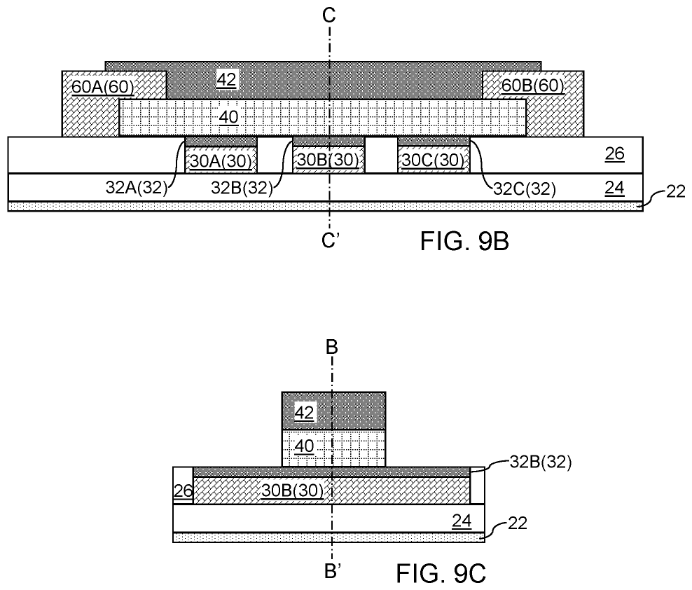

Referring to FIGS. 9A-9C, a photoresist layer (not shown) may be applied over the optional sacrificial cover material layer 45L (in embodiments that include the optional sacrificial cover material layer 45L) and the PCM-capping dielectric layer 42L, and may be lithographically patterned to provide an elongated photoresist material portion covers the top surface of the PCM line 40 and at least a portion of the top surfaces of the first electrode 60A and the second electrode 60B. Unmasked portions of the optional sacrificial cover material layer 45L and the PCM-capping dielectric layer 42L may be etched by performing an anisotropic etch process that uses the patterned photoresist material portion as an etch mask. A remaining portion of the PCM-capping dielectric layer 42L comprises a PCM-capping dielectric plate 42. Any remaining portion of the optional sacrificial cover material layer 45L may be removed by performing an etch process (such as an isotropic etch process) that etches the material of the sacrificial cover material layer 45L selective to the materials of the insulating matrix layer 26, the PCM line 40, the heater-capping dielectric plates 32, the electrodes 60, and the PCM-capping dielectric plate 42. For example, a wet etch process using hydrofluoric acid may be used if the sacrificial cover material layer 45L comprises undoped silicate glass or a doped silicate glass.

In some embodiments, the PCM-capping dielectric layer 42L may be etched to form a PCM-capping dielectric plate 42 that encapsulates any remaining exposed surfaces of the PCM line 40 (i.e., any exposed portions of the PCM line 40 not encapsulated by the first electrode 60A at a first end portion of the PCM line 40 and by the second electrode 60B at a second end portion of the PCM line 40). For example, a middle portion of the PCM line 40 may be encapsulated by the PCM-capping dielectric plate 42, such that a bottom surface of the PCM-capping dielectric plate 42 is in contact with a top surface of the PCM line 40, sidewalls of the PCM-capping dielectric plate 42 are in contact with sidewalls of the PCM-capping dielectric plate 42, and bottom surfaces of the PCM-capping dielectric plate 42 is in contact with top surfaces of the insulating matrix layer 26 and the heater-capping dielectric plates 32.

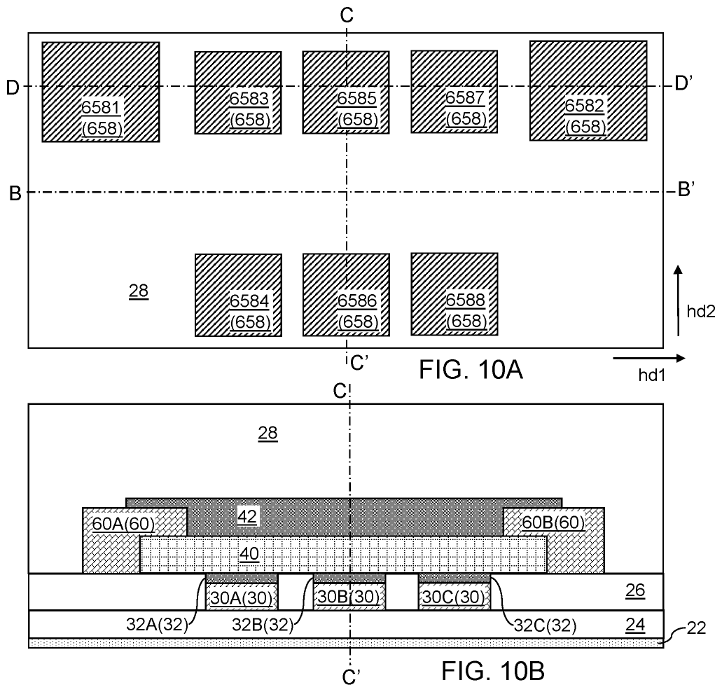

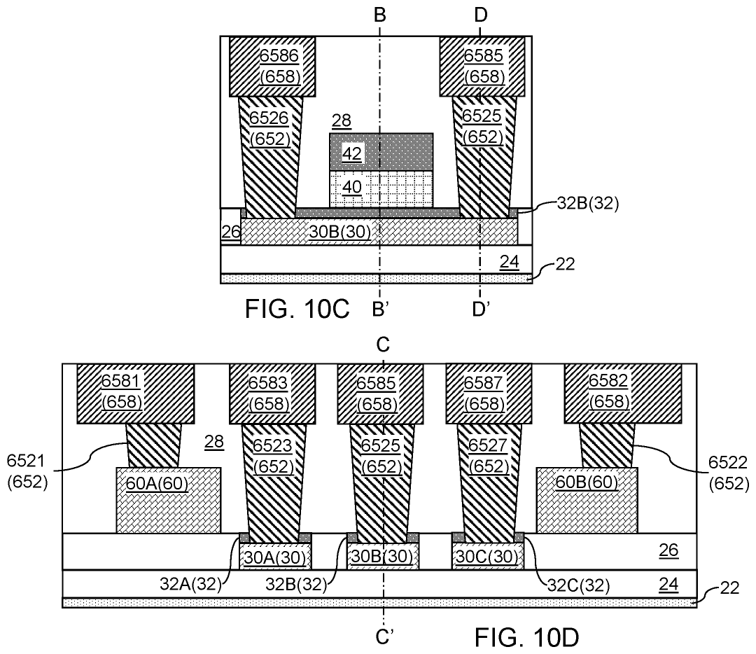

Referring to FIGS. 10A-10D, a dielectric material layer 28 may be deposited over exposed top surfaces of the insulating matrix layer 26, the heater-capping dielectric plates 32, the electrodes 60, and the PCM-capping dielectric plate 42. The dielectric material layer 28 may also be referred to as a switch-level dielectric material layer 28. Additional metal interconnect structures (652, 658) may be formed in the switch-level dielectric material layer 28. The additional metal interconnect structures (652, 658) are herein referred to as switch-level metal interconnect structures (652, 658), and may comprise switch-level metal line structures 658 and switch-level metal via structures 652.

The switch-level metal via structures 652 may comprise a first electrode contact via structure 6521 contacting the first electrode 60A, a second electrode contact via structure 6522 contacting the second electrode 60B, a first heater contact via structure 6523 contacting a first end portion of the first heater line 30A and sidewalls of the first heater-capping dielectric plate 32A, a second heater contact via structure 6524 contacting a second end portion of the first heater line 30A and sidewalls of the first heater-capping dielectric plate 32A, a third heater contact via structure 6525 contacting a first end portion of the second heater line 30B and sidewalls of the second heater-capping dielectric plate 32B, a fourth heater contact via structure 6526 contacting a second end portion of the second heater line 30B and sidewalls of the second heater-capping dielectric plate 32B, a fifth heater contact via structure 6527 contacting a first end portion of the third heater line 30C and sidewalls of the third heater-capping dielectric plate 32C, and a sixth heater contact via structure 6528 contacting a second end portion of the third heater line 30C and sidewalls of the third heater-capping dielectric plate 32C. The switch-level metal line structures 658 may comprise a first electrode connection metal line structure 6581 contacting a top surface of the first electrode contact via structure 6521, a second electrode connection metal line structure 6582 contacting a top surface of the second electrode contact via structure 6522, a first heater connection metal line structure 6583 contacting a top surface of the first heater contact via structure 6523, a second heater connection metal line structure 6584 contacting a top surface of the second heater contact via structure 6524, a third heater connection metal line structure 6585 contacting a top surface of the third heater contact via structure 6525, a fourth heater connection metal line structure 6586 contacting a top surface of the fourth heater contact via structure 6526, a fifth heater connection metal line structure 6587 contacting a top surface of the fifth heater contact via structure 6527, and a sixth heater connection metal line structure 6588 contacting a top surface of the sixth heater contact via structure 6528.

Generally, semiconductor devices 701 may be formed on the substrate 8, and metal via and interconnect structures (612, 618, 622, 628, 631, 638, 642, 648) and dielectric material layers (601, 610, 620, 630, 640) may be formed over the substrate 8. The metal via and interconnect structures (612, 618, 622, 628, 631, 638, 642, 648) are formed in the dielectric material layers (601, 610, 620, 630, 640). The dielectric isolation layer 24 is formed over metal via and interconnect structures (612, 618, 622, 628, 631, 638, 642, 648). The end portions of the first heater line 30A, the second heater line 30B, the third heater line 30C, the first electrode 60A, and the second electrode 60B may be electrically connected to a respective one of the metal via and interconnect structures (612, 618, 622, 628, 631, 638, 642, 648) by forming additional metal interconnect structures (652, 658), which include additional switch-level metal via structures (not illustrated) that connect a respective one of the switch-level metal line structures 658 to a respective one of the fourth metal line structures 648. Subsequently, bonding-level structures such as a passivation dielectric layer and metal bonding pads may be formed over the switch-level dielectric material layer as needed.

The phase-change material (PCM) line 40 comprises a middle portion overlying the first heater line 30A, the second heater line 30B, and the third heater line 30C, a first end portion contacting sidewalls and a bottom surface of the first electrode 60A, and a second end portion contacting sidewalls and a bottom surface of the second electrode 60B.

For illustrative purposes, the switch as shown in FIGS. 10A-10D includes three heater lines 30 including the first heater line 30A, the second heater line 30B, and the third heater line 30C positioned beneath but electrically isolated from the PCM line 40. However, fewer or more heater lines may be formed for operation with the PCM line 40. For example, two heater lines may be formed to work in conjunction with the PCM line 40. As another example, four or more heater lines may be formed to work in conjunction with the PCM line 40.

Transmitting a short pulse width signal (i.e., RESET) through a heater line 30 may activate a PCM cell (i.e., the area of overlap between a PCM line 40 and a heater line 30 in a plan view) to enter a high resistance state in which that PCM cell functions as a resistor. Transmitting a long pulse width signal (i.e., SET) through a heater line 30 may activate a PCM cell to enter a high resistance state in which that PCM cell functions as a capacitor. Current flowing through the PCM line 40 may be affected by the various resistance and capacitance values biased within a PCM cell via the heater line 30.

By implementing multiple heater lines 30 within the switch structure, various resistance and capacitance values may be achieved in the PCM line 40 simultaneously when transmitting short pulse width and/or long pulse width signals through the heater lines 30. In some embodiments, the heater lines 30 may be driven by a single switch or otherwise controlled by a shared write driver to activate the first PCM cell, the second PCM cell, and the third PCM cell simultaneously. In some embodiments, the heater lines 30 may be driven individually, such that the first PCM cell, the second PCM cell, and the third PCM cell may be activated individually to create multiple unique total resistance values along the channel length of the PCM line 40 during each read operation. For example, implementing three heater lines 30 may allow the PCM line 40 to adjust to any total resistance value within an 8-bit range of resistance values that may be used to tune the switch (e.g., within a bandpass filter application). The following Table 1 illustrates the various resistance states achievable (i.e., bit) within the PCM line 40 when biasing the PCM cells with short pulse width signals to enter a high resistance state (HR) and with long pulse width signals to enter a low resistance state (LR), in which PCM-1, PCM-2, and PCM-3 represents the first PCM cell, the second PCM cell, and the third PCM cell respectively.

TABLE 1

| bit | 0 | 1 | 2 | 3 | 4 | 5 | 6 | 7 |
|---|---|---|---|---|---|---|---|---|
| PCM-1 | HR 1 | LR1 | HR 1 | LR1 | LR1 | HR1 | HR 1 | LR1 |
| PCM-2 | HR2 | LR2 | LR2 | HR2 | LR2 | HR2 | LR2 | HR2 |
| PCM-3 | HR3 | LR3 | LR3 | LR3 | HR3 | LR3 | HR3 | HR3 |

The first PCM cell (PCM-1), the second PCM cell (PCM-2), and the third PCM cell (PCM-3) may be read in series, from the first electrode 60A to the second electrode 60B, or from the second electrode 60B to the first electrode 60A, to determine the total resistance within the PCM line 40 based on the heater lines 30 each being transmitted with long pulse width or short pulse width signals.

By allowing a PCM line 40 to be configured with more than two resistance states via implementation of two or more heater lines 30, circuit size and operations may be simplified to reduce the overall size of the semiconductor structure and PCB real estate used within a chip package. Utilizing a switch with a PCM line and multiple heater lines may replace several binary-state PCM lines that implement a single PCM line and a single corresponding heater line, therefore reducing the chip size and/or opening up more space for additional semiconductor structures. For example, in a band pass filter application, a single switch with one PCM line and multiple heater lines may replace multiple separate switches each using a single PCM line 40 and a single heater line 30. A switch with a PCM line 40 and multiple heater lines may further provide a larger range of tunable frequencies (e.g., MHz to GHz tunable band pass filter), allowing for increased applications. Furthermore, as the device may be fabricated at the back end of line (BEOL), the switch with multiple heater lines may be implemented in a wider range of technologies and applications.

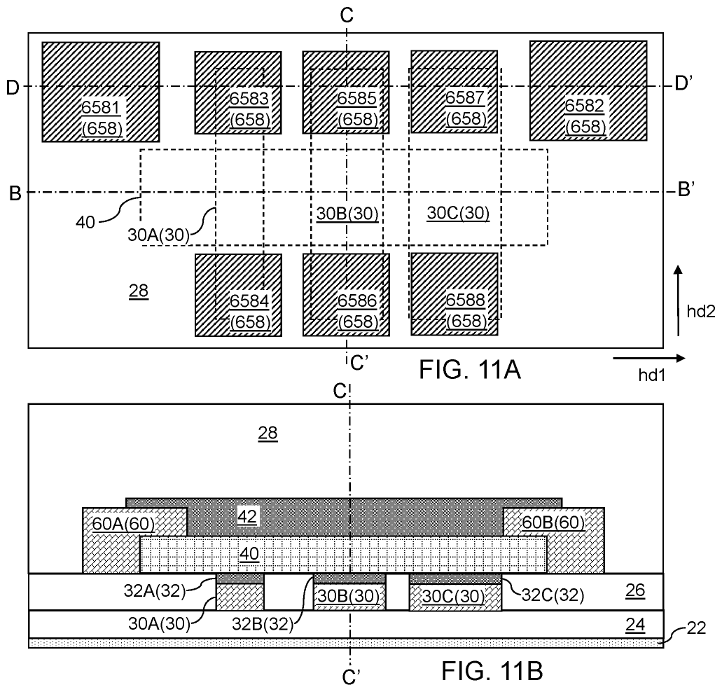

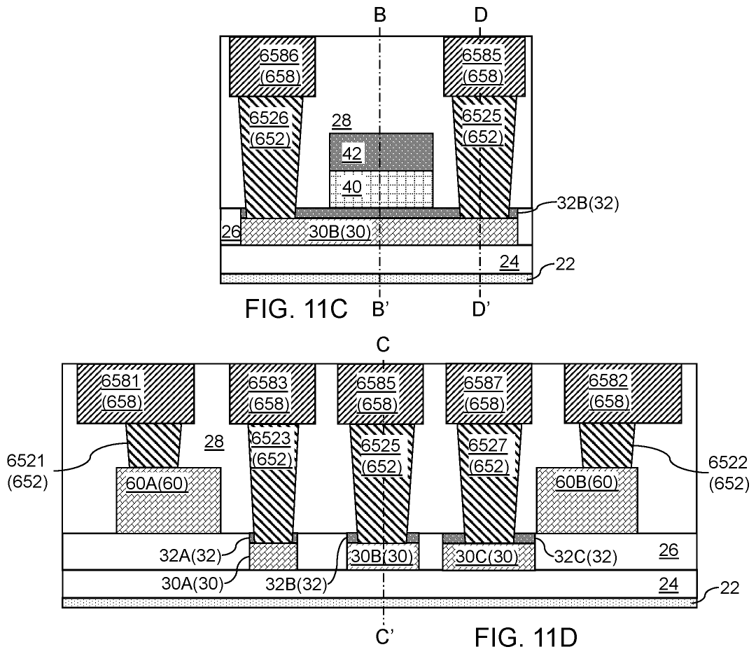

Referring to FIGS. 11A-11D, a first alternative embodiment of a PCM switch structure with multiple heater lines having various widths is illustrated. The switch structure as illustrated in FIGS. 11A-11D may be formed in a similar manner as the processes described with reference to FIGS. 10A-10D. For ease of illustration, in the plan view shown in FIG. 11A, the PCM line 40 and the heater lines 30 are outlined by dashed lines to indicate that they are positioned beneath observable layers of the switch structure.

In some embodiments (e.g., as illustrated in FIGS. 10A-10D), the heater lines 30 may have a same width in a first horizontal direction hd1. In some embodiments (e.g., as illustrated in FIGS. 11A-110D), the heater lines 30 may have different widths in a first horizontal direction hd1 at the overlap (i.e., first PCM cell, second PCM cell, third PCM cell) between the PCM line 40 and the heater lines 30. For example, the first heater line 30A may have a different width at the first PCM cell than the width of the second heater line 30B at the second PCM cell and the width of the third heater line 30C at the third PCM cell. Likewise, the second heater line 30B may have a different width at the second PCM cell than the width of the third heater line 30C at the third PCM cell. For example, as illustrated in FIGS. 11A, 11B, and 11D, the first heater line 30A may have a width that is smaller than both the second heater line 30B width and the third heater line 30C width, the second heater line 30B may have a width that is larger than the first heater line 30A width but is smaller than the third heater line 30C width, and the third heater line 30C may have a width that is larger than both the first heater line 30A width and the second heater line 30B width. The widths of the heater lines 30 may be designed and formed in any size and order (i.e., not just from smallest to largest in the direction of current flow as illustrated in FIGS. 11A-111D). For example, in other embodiments, the second heater line 30B may have a larger width than both the first heater line 30A and the third heater line 30C.

In some embodiments including three or more heater lines 30, some heater lines 30 may have a same width in the first horizontal direction hd1 and some heater lines 30 may have a different width than the other same-width heater lines 30. For example, the first heater line 30A may have a same width as the second heater line 30B, which both have a different width than the third heater line 30C. Similarly, the first heater line 30A and the third heater line 30C may have an equal width that is different from the width of the second heater line 30B.

Designing and forming switches with multiple heater lines 30 having various widths in the first horizontal direction hd1 may allow for fine-tuning of resistance and capacitance values observed within the PCM line 40.

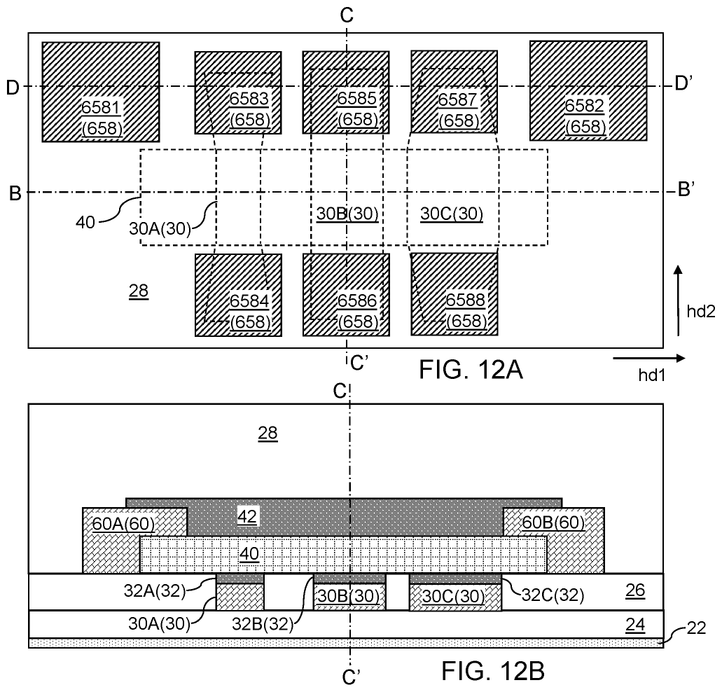

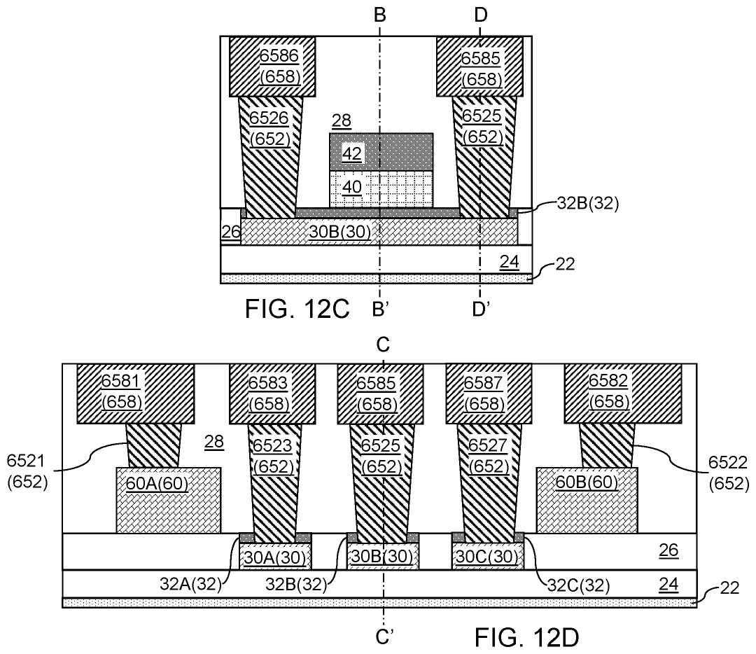

Referring to FIGS. 12A-12D, a second alternative embodiment of a PCM switch structure with multiple heater lines with tapered sidewalls is illustrated. The switch structure as illustrated in FIGS. 12A-12D may be formed in a similar manner as the processes described with reference to FIGS. 10A-10D. For ease of illustration, in the plan view shown in FIG. 12A, the PCM line 40 and the heater lines 30 are outlined by dashed lines to indicate that they are positioned beneath observable layers of the switch structure. The heater lines 30 may have various widths at the first PCM cell, second PCM cell, and third PCM cells similar to as described with reference to FIGS. 11A-11D. In some embodiments, the various widths of the heater lines 30 may be achieved by forming the heater lines 30 with tapered sidewalls, such that the widths of each of the heater lines 30 may be the same at a first end and a second end, but the width of each heater line under the PCM line 40 may vary. For example, in a plan view, the first heater line 30A may be formed to have sidewalls tapered inward to achieve a smaller width under the PCM line 40 as compared to the remaining heater lines 30 under the PCM line 40. As another example, in a plan view, the third heater line 30C may be formed to have sidewalls tapered outward to achieve a larger width compared to the remaining heater lines 30.

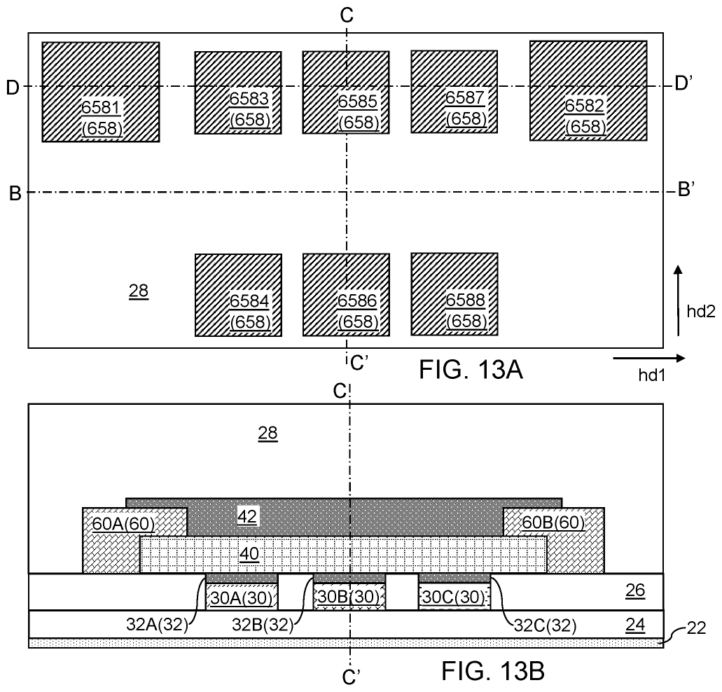

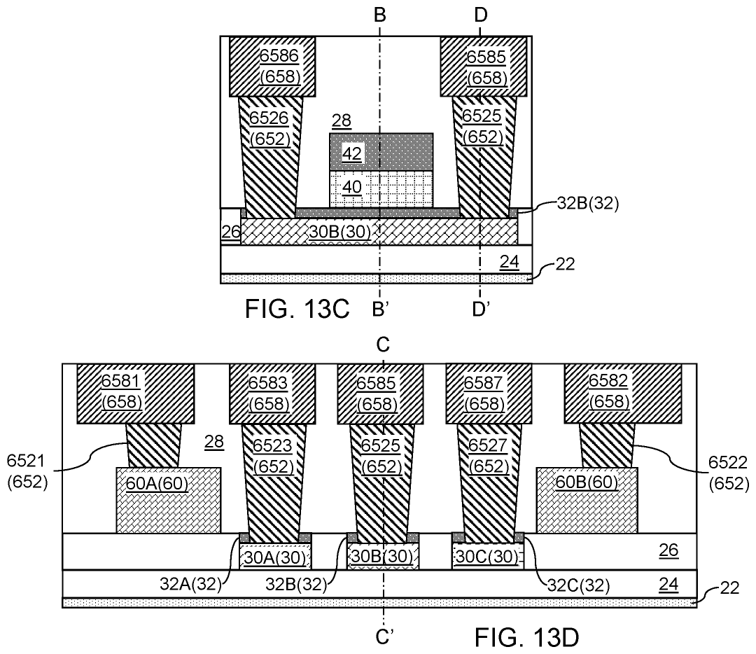

Referring to FIGS. 13A-13D, a third alternative embodiment of a PCM switch structure with multiple heater lines having various materials is illustrated. The switch structure as illustrated in FIGS. 13A-13D may be formed in a similar manner as the processes described with reference to FIGS. 10A-10D. The heater lines 30 may be formed using different materials that have varying effects on the reactivity of the PCM line 40 when short pulse width or a long pulse width signals are conveyed through the heater lines 30. Thus, resistance and capacitance values within the PCM line 40 exerted across a read operation may be fine-tuned by using different materials to form the heater lines 30 while the heater lines 30 have the same widths in the first horizontal direction hd1. For example, the heater lines 30 may have a same width, the first heater line 30A may comprise copper, the second heater line 30B may comprise gold, and the third heater line 30C may comprise tungsten. Thus, transmitting short pulse width signals having a same amplitude and frequency across each of the varying-material heater lines 30 will results in different resistance values observed within the PCM line 40 during a read operation. In some embodiments, two or more heater lines 30 may comprise a same material that is different from the material of one or more other heater lines 30.

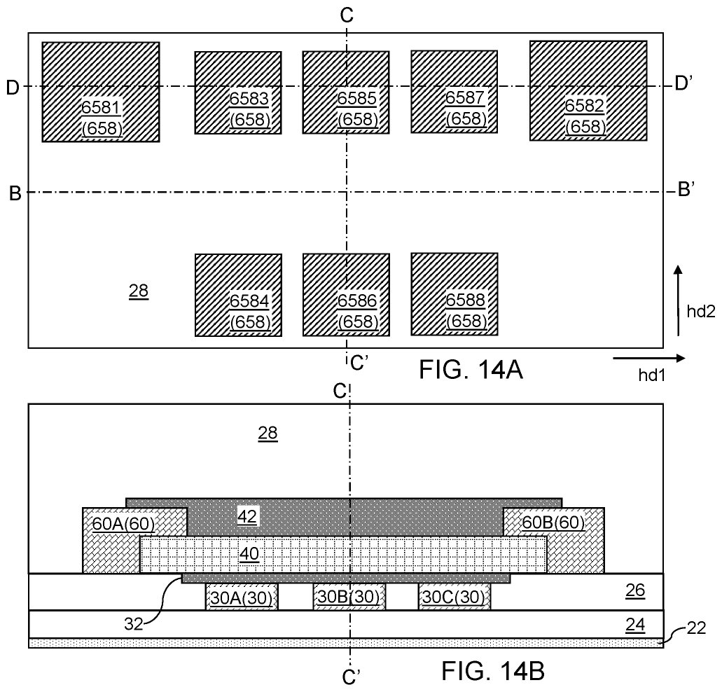

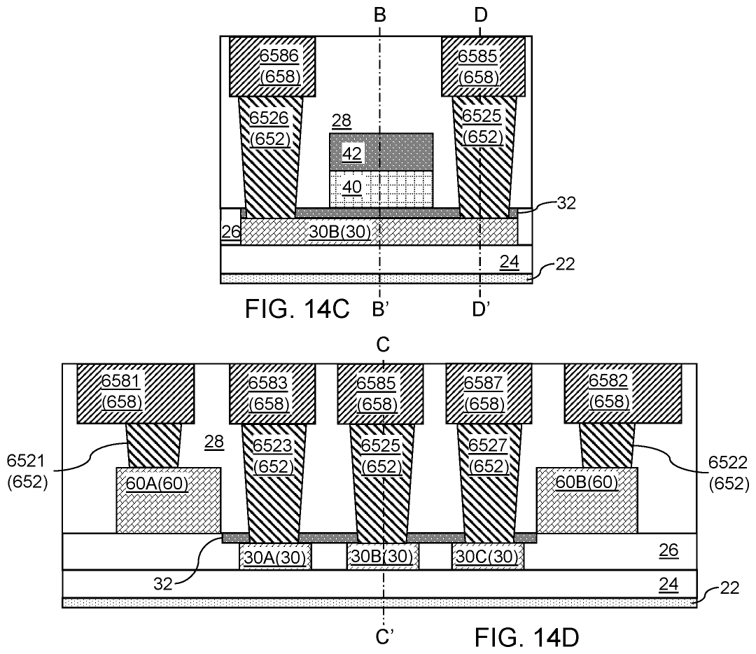

Referring to FIGS. 14A-14D, a fourth alternative embodiment of a PCM switch structure with multiple heater lines contacting a single heater-capping dielectric plates 32 is illustrated. The switch structure as illustrated in FIGS. 14A-14D may be formed in a similar manner as the processes described with reference to FIGS. 10A-10D. In some embodiments, separate heater-capping dielectric plates 32 may contact top surfaces of each respective heater line 30 and bottom surfaces of the PCM line 40 to electrically isolate the heater lines 30 from the PCM line 40. In some embodiments, as illustrated in FIGS. 14A-14D, a single planar heater-capping dielectric plate 32 be formed (i.e., as described with reference to FIGS. 2A-3C) to contact all top surfaces of the heater lines 30 and the entirety of the bottom surface of the PCM line 40 to electrically isolate all heater lines 30 from the PCM line 40.

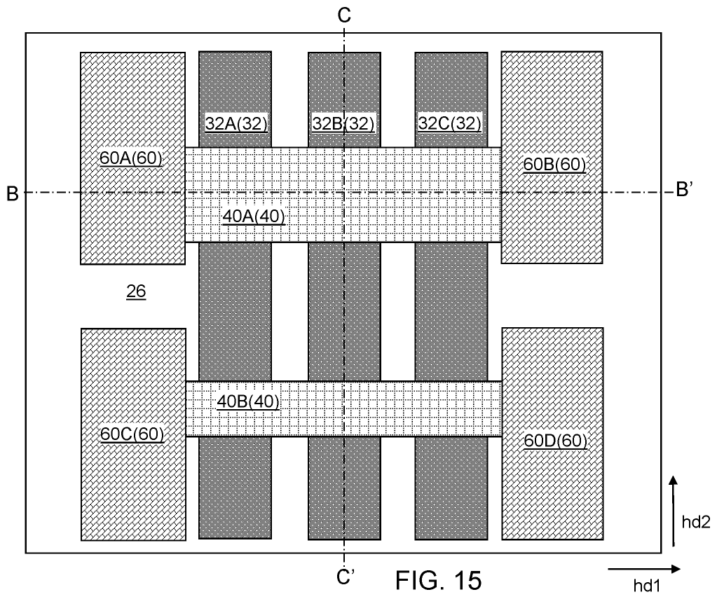

Referring to FIG. 15, a fifth alternative embodiment of a PCM switch structure with multiple heater lines 30 and multiple PCM lines 40 is illustrated. The switch structure as illustrated in FIG. 15 may be formed in a similar manner as the processes described with reference to FIGS. 10A-10D. FIG. 15 illustrates an alternate switch structure at the manufacturing phase as shown in FIGS. 7A-7C, but with a first PCM line 40A and a second PCM line 40B. In some embodiments, two or more PCM lines 40 may be formed over the heater lines 30. For example, a first PCM line 40A and a second PCM line 40B may be formed on top surfaces of heater-capping dielectric plates 32 or a single heater-capping dielectric plate 32 to overlay the heater lines 30. The first PCM line 40A and the second PCM line 40B may be electrically connected to separate electrodes 60; the first PCM line 40A may be contacting and electrically connected to the first electrode 60A and the second electrode 60B, and the second PCM line 40B may be contacting and electrically connected to a third electrode 60C and a fourth electrode 60D.

The first PCM line 40A may have a different width than the second PCM line 40B in a second horizontal direction hd2. Thus, the heater lines 30 may communicate short pulse width and long pulse width signals to effectuate various resistances and capacitance values within each PCM cell for each of the PCM lines 40. For example, the PCM line 40A may have a first PCM cell, a second PCM cell, and a third PCM cell corresponding to the overlap area with the PCM line 40A and the first heater line 30A, the second heater line 30B, and the third heater line 30C respectively in a plan view. be wider than the second PCM line 40B in the second horizontal direction. The second PCM line 40B may have a fourth PCM cell, a fifth PCM cell, and a sixth PCM cell corresponding to the overlap area with the second PCM line 40B and the first heater line 30A, the second heater line 30B, and the third heater line 30C respectively in a plan view. The first PCM cell has a larger area than the fourth PCM cell, the second PCM cell has a larger area than the fifth PCM cell, and the third PCM cell has a larger area than the sixth PCM cell, Therefore, the first, second, and third PCM cells will exhibit higher resistances values when activated with a short pulse width signal than the fourth, fifth, and sixth PCM cells respectively.

In some embodiments, resistance of the PCM lines 40 may also be fine-tuned by varying the length of the PCM lines 40 in the first horizontal direction hd1 with respect to other PCM lines 40 within the switch structure (i.e., where a longer PCM line 40 has a larger default resistance value than a shorter PCM line). For example, the channel length of the first PCM line 40A may be longer than the channel length of the second PCM line 40B in the first horizontal direction hd1, and therefore having a higher default resistance value assuming they are the same width in the second horizontal direction.

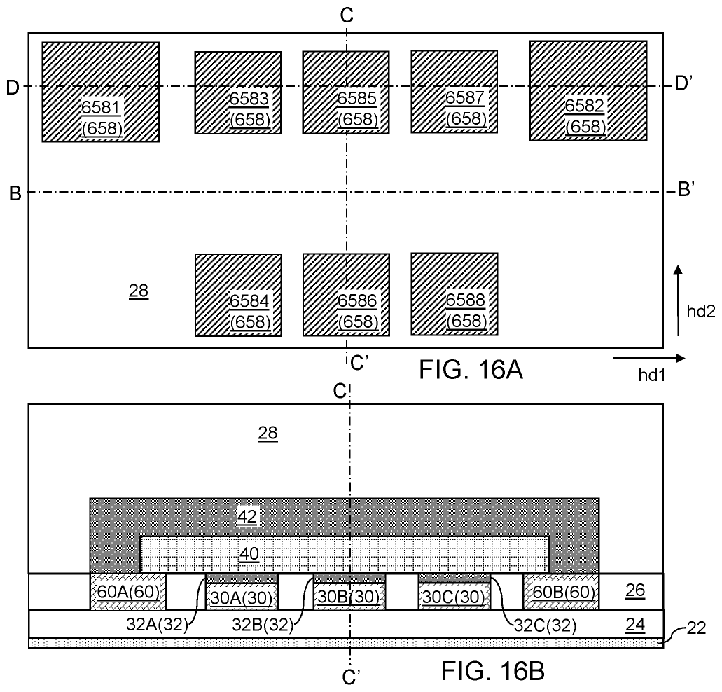

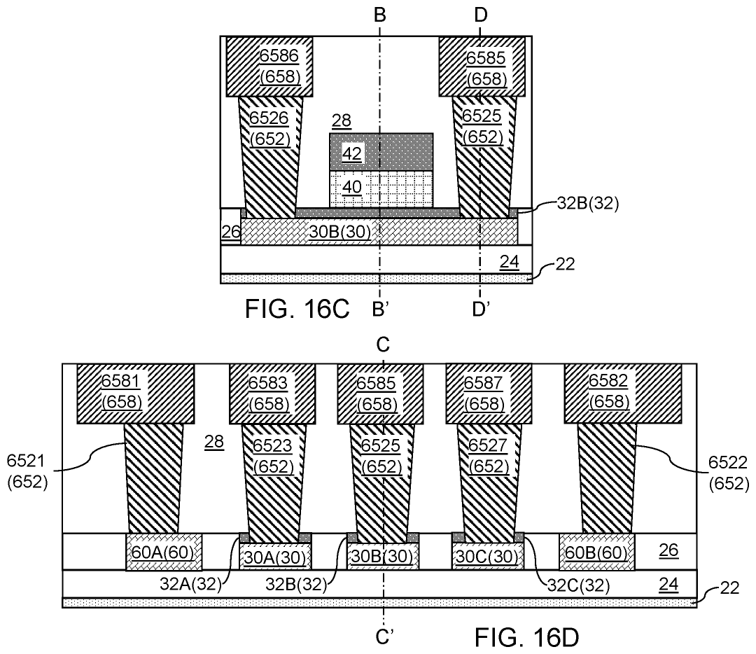

Referring to FIGS. 16A-16D, a sixth alternative embodiment of a PCM switch structure with multiple heater lines is illustrated. The processing steps of FIGS. 1-10D may be performed mutatis mutandis to form the switch structure as illustrated in FIGS. 16A-16D, with variation in the order and relative positioning of the electrodes 60, heater lines 30, and PCM line 40. The electrodes 60 may be in a same horizontal plane as the heater lines 30. A top surface of the first electrode 60A may be in contact with a bottom surface of the first end portion of the PCM line 40, and top surface of the second electrode 60B may be in contact with a bottom surface of the second end portion of the PCM line 40. The electrodes 60 may be formed during the same process as the heater lines 30 within the insulating matrix layer 26.

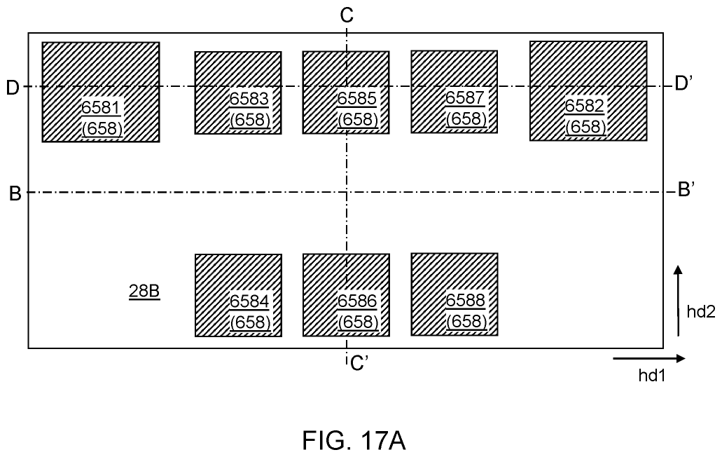

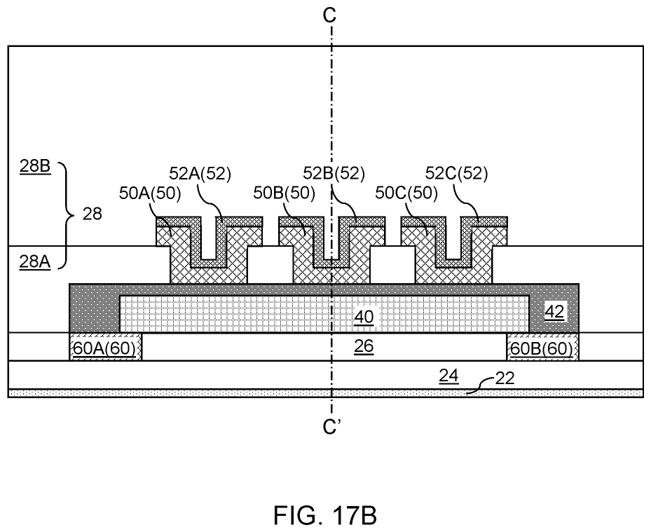

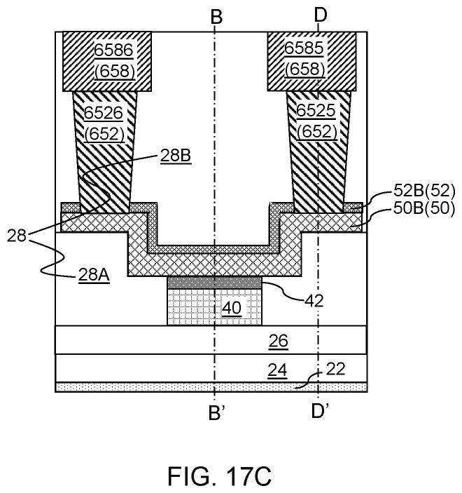

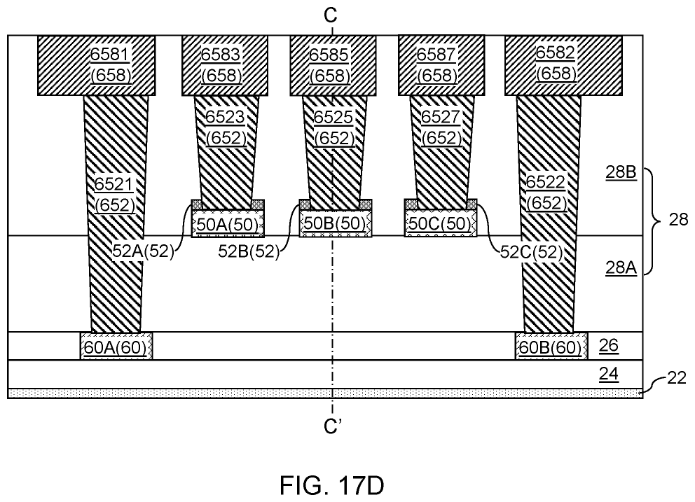

Referring to FIGS. 17A-17D, a seventh alternative embodiment of a PCM switch structure with multiple heater lines is illustrated. The processing steps of FIGS. 1-10D may be performed mutatis mutandis to form the switch structure as illustrated in FIGS. 17A-17D, with variation in the order and relative positioning of the electrodes 60, trench heater lines 50, and PCM line 40. Two or more trench heater lines 50 may be formed above the PCM line 40. For example, a first trench heater line 50A, a second trench heater line 50B, and a third trench heater line 50C may be formed over the PCM line 40 and in contact with a top surface of the PCM-capping dielectric plate 42. A first heater-capping dielectric plate 52A may be formed over the first trench heater line 50A to be in contact with top surfaces and sidewalls of the first trench heater line 50A. A second heater-capping dielectric plate 52B may be formed over the second trench heater line 50B to be in contact with top surfaces and sidewalls of the second trench heater line 50B. A third heater-capping dielectric plate 52C may be formed over the third trench heater line 50C to be in contact with top surfaces and sidewalls of the third trench heater line 50C. The trench heater lines 50 and heater-capping dielectric plates 52 may be formed in multiple processes within a lower dielectric material layer 28A and an upper dielectric material layer 28B.

The switch-level metal via structures 652 may comprise a first electrode contact via structure 6521 contacting the first electrode 60A, a second electrode contact via structure 6522 contacting the second electrode 60B, a first trench heater contact via structure 6523 contacting a first end portion of the first trench heater line 50A and sidewalls of the first heater-capping dielectric plate 52A, a second heater contact via structure 6524 contacting a second end portion of the first trench heater line 50A and sidewalls of the first heater-capping dielectric plate 52A, a third heater contact via structure 6525 contacting a first end portion of the second trench heater line 50B and sidewalls of the second heater-capping dielectric plate 52B, a fourth heater contact via structure 6526 contacting a second end portion of the second trench heater line 50B and sidewalls of the second heater-capping dielectric plate 52B, a fifth heater contact via structure 6527 contacting a first end portion of the third trench heater line 50C and sidewalls of the third heater-capping dielectric plate 52C, and a sixth heater contact via structure 6528 contacting a second end portion of the third trench heater line 50C and sidewalls of the third heater-capping dielectric plate 52C.

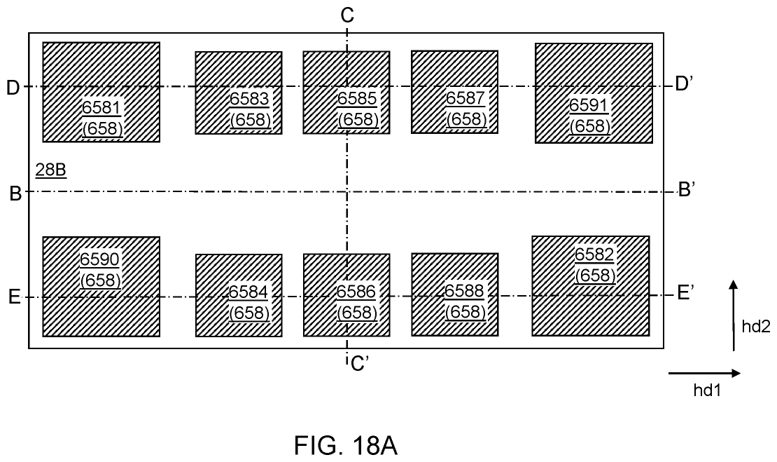

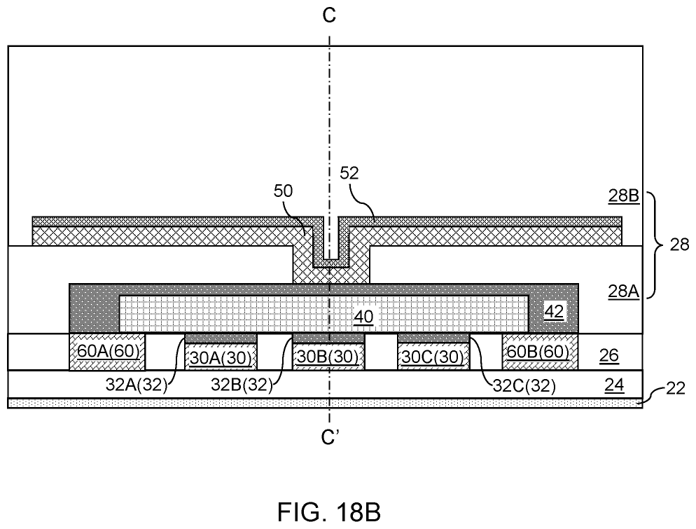

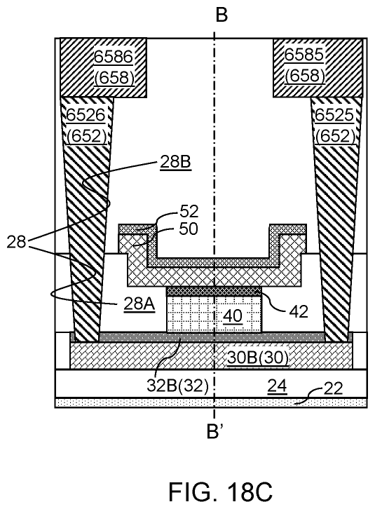

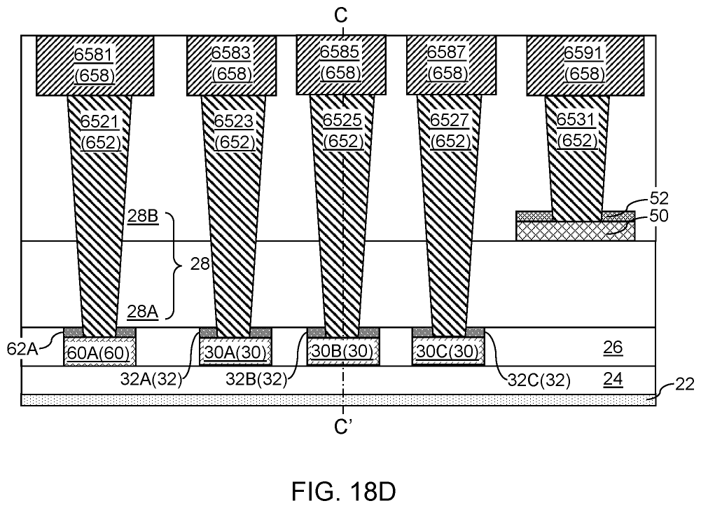

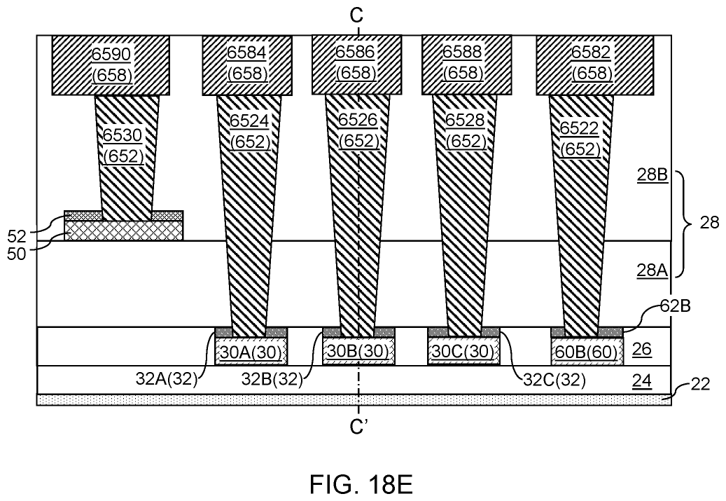

Referring to FIGS. 18A-18E, an eighth alternative embodiment of a PCM switch structure with multiple heater lines is illustrated. The processing steps of FIGS. 1-10D may be performed mutatis mutandis to form the switch structure as illustrated in FIGS. 18A-18E, with variation in the order and relative positioning of the electrodes 60, heater lines 30, trench heater line 50, and PCM line 40. Multiple heater lines 30 and/or trench heater lines 50 may be formed beneath and above the PCM line 40 respectively. For example, as illustrated in FIG. 18B, the first heater line 30A, the second heater line 30B, and the third heater line 30C may be formed beneath the PCM line 40, and a trench heater line 50 may be formed above the PCM line 40 and in contact with a top surface of the PCM-capping dielectric plate 42. A heater-capping dielectric plate 52 may be formed over the trench heater line 50 to be in contact with top surfaces and sidewalls of the trench heater line 50. The trench heater line 50 and heater-capping dielectric plate 52 may be formed in multiple processes within a lower dielectric material layer 28A and an upper dielectric material layer 28B. As another example (not shown), a heater line 30 may be formed beneath the PCM line 40, and a two or more trench heater lines 50 may be formed over the PCM line 40.

The switch-level metal via structures 652 may comprise a first electrode contact via structure 6521 contacting the first electrode 60A, a second electrode contact via structure 6522 contacting the second electrode 60B, a first heater contact via structure 6523 contacting a first end portion of the first heater line 30A and sidewalls of the first heater-capping dielectric plate 32A, a second heater contact via structure 6524 contacting a second end portion of the first heater line 30A and sidewalls of the first heater-capping dielectric plate 32A, a third heater contact via structure 6525 contacting a first end portion of the second heater line 30B and sidewalls of the second heater-capping dielectric plate 32B, a fourth heater contact via structure 6526 contacting a second end portion of the second heater line 30B and sidewalls of the second heater-capping dielectric plate 32B, a fifth heater contact via structure 6527 contacting a first end portion of the third heater line 30C and sidewalls of the third heater-capping dielectric plate 32C, a sixth heater contact via structure 6528 contacting a second end portion of the third heater line 30C and sidewalls of the third heater-capping dielectric plate 32C, a seventh heater contact via structure 6530 contacting a first end portion of the trench heater line 50 and sidewalls of the heater-capping dielectric plate 52, and a sixth heater contact via structure 6531 contacting a second end portion of the trench heater line 50 and sidewalls of the heater-capping dielectric plate 52. The trench heater line 50 may be formed to be positioned over the length of the PCM line 40.

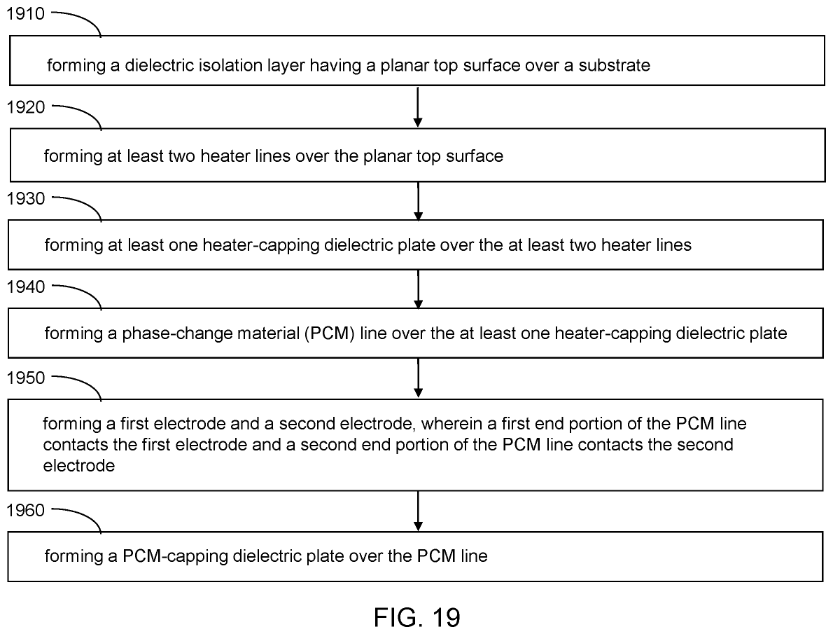

Referring to FIG. 19, a first flowchart illustrates the general processing steps for manufacturing the semiconductor devices according to some embodiments of the present disclosure.

Referring to step 1910 and FIG. 1, a dielectric isolation layer 24 having a planar top surface 25 may be formed over a substrate 8.

Referring to step 1920 and FIGS. 2A-2C, at least two heater lines 30 may be formed over the planar top surface 25.

In some embodiments, forming the at least two heater lines 30 over the planar top 25 may include forming a first heater line 30 (e.g., 30A) having a first width in a first horizontal direction hd1, and forming a second heater line 30 (e.g., 30B, 30C) having a second width in the first horizontal direction hd1, in which the first width is different from the second width.

In some embodiments, forming the at least two heater lines 30 over the planar top surface 25 may include forming a first heater line 30 (e.g., 30A) with a first material, and forming a second heater line 30 (e.g., 30B, 30C) with a second material, in which the first material is different from the second material.

Referring to step 1930 and FIGS. 2A-2C and 14A-14D, at least one heater-capping dielectric plate 32 may be formed over the at least two heater lines 30.

Referring to step 1940 and FIGS. 4A-5C, a phase-change material (PCM) line 40 may be formed over the at least one heater-capping dielectric plate 32.

Referring to step 1950 and FIGS. 6A-7C, a first electrode 60A and a second electrode 60B may be formed, in which a first end portion of the PCM line 40 contacts the first electrode 60A and a second end portion of the PCM line 40 contacts the second electrode 60B.

In some embodiments, the first end portion of the PCM line 40 contacts a sidewall and a bottom surface of the first electrode 60A, the second end portion of the PCM line 40 contacts a sidewall and a bottom surface of the second electrode 60B, and a middle portion of the PCM line 40 between the first end portion and the second end portion overlies the at least two heater lines 30.

Referring to step 1960 and FIGS. 8A-9C, a PCM-capping dielectric plate 42 may be formed over the PCM line 40.

In some embodiments, a first dielectric material layer 28A may be formed over the PCM-capping dielectric plate 42, a trench in the first dielectric material layer 28A may be formed, in which a top surface of a horizontally-extending portion of the PCM-capping dielectric plate 42 is exposed, a conductive material may be deposited over the first dielectric material layer 28A and in the trench to be in contact with exposed portions of the PCM-capping dielectric plate 42, and the conductive material may be patterned into a trench heater line 50.

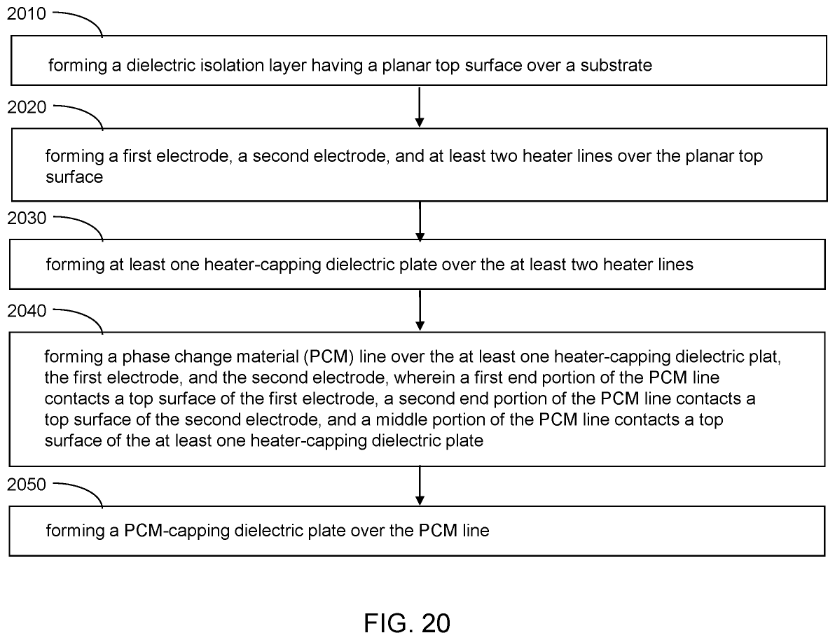

Referring to FIG. 20, a first flowchart illustrates the general processing steps for manufacturing the semiconductor devices according to some embodiments of the present disclosure.

Referring to step 2010 and FIGS. 1, 16A-16D, and 18A-18E, a dielectric isolation layer 24 having a planar top surface 25 may be formed over a substrate 8.

Referring to step 2020 and FIGS. 2A-2C, 16A-16D, and 18A-18E, a first electrode 60A, a second electrode 60B, and at least two heater lines 30 may be formed over the planar top surface 25.

Referring to step 2030 and FIGS. 2A-2C, 16A-16D, and 18A-18E, at least one heater-capping dielectric plate 32 may be formed over the at least two heater lines 30.

Referring to step 2040 and FIGS. 4A-5C, 16A-16D, and 18A-18E, a phase change material (PCM) line 40 may be formed over the at least one heater-capping dielectric plate 32, the first electrode 60A, and the second electrode 60B, in which a first end portion of the PCM line 40 contacts a top surface of the first electrode 60A, a second end portion of the PCM line 40 contacts a top surface of the second electrode 60B, and a middle portion of the PCM line 40 contacts a top surface of the at least one heater-capping dielectric plate 32.

Referring to step 2050 and FIGS. 8A-9C, 16A-16D, and 18A-18E, a PCM-capping dielectric plate 42 may be formed over the PCM line 40.

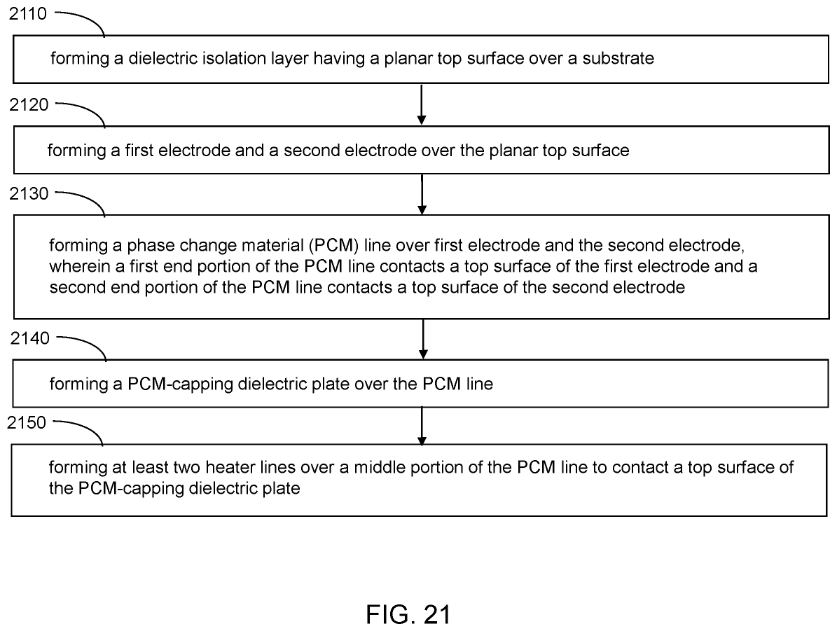

Referring to FIG. 21, a first flowchart illustrates the general processing steps for manufacturing the semiconductor devices according to some embodiments of the present disclosure.

Referring to step 2110 and FIGS. 17A-17D, a dielectric isolation layer 24 having a planar top surface 25 may be formed over a substrate 8.

Referring to step 2120 and FIGS. 17A-17D, a first electrode 60A and a second electrode 60B may be formed over the planar top surface 25.

Referring to step 2130 and FIGS. 17A-17D, a phase change material (PCM) line 40 may be formed over first electrode 60A and the second electrode 60B, in which a first end portion of the PCM line 40 contacts a top surface of the first electrode 60A and a second end portion of the PCM line 40 contacts a top surface of the second electrode 60B.

Referring to step 2140 and FIGS. 17A-17D, a PCM-capping dielectric plate 42 may be formed over the PCM line 40.

Referring to step 2150 and FIGS. 17A-17D, at least two heater lines 30 may be formed over a middle portion of the PCM line 40 to contact a top surface of the PCM-capping dielectric plate 42.

Referring to all drawings and according to various embodiments of the present disclosure, a semiconductor structure is provided, which comprises: a first electrode 60A; a second electrode 60B; a phase-change material (PCM) line 40 in contact with and positioned between the first electrode 60A and the second electrode 60B; at least two heater lines 30 positioned between the first electrode 60A and the second electrode 60B; and an isolation layer (e.g., heater-capping dielectric plate 32) positioned between the PCM line 40 and the at least two heater lines 30.

In some embodiments, the at least two heater lines 30 may include a first heater line 30 (e.g., 30A) positioned in a first vertical plane as the PCM line 40 in a vertical cross-sectional view, and a second heater line 30 (e.g., 30B, 30C) positioned in a second vertical plane as the PCM line 40 in a vertical cross-sectional view, in which the first heater line 30 (e.g., 30A) and the second heater line 30 (e.g., 30B, 30C) are in a same horizontal plane in a vertical cross-sectional view.

In some embodiments, the first heater line 30 may be a same width as the second heater line 30 (e.g., 30B, 30C) in a first horizontal direction. In some embodiments, the first heater line 30 (e.g., 30A) may be a different width than the second heater line 30 (e.g., 30B, 30C) in a first horizontal direction. In some embodiments, the first heater line 30 (e.g., 30A) may be a same material as the second heater line 30 (e.g., 30B, 30C). In some embodiments, the first heater line 30 (e.g., 30A) may be a different material than the second heater line 30 (e.g., 30B, 30C).

In some embodiments, the at least two heater lines may include a third heater line 30 (e.g., 30B, 30C), and the third heater line 30 (e.g., 30B, 30C) may be a same width as the first heater line 30 (e.g., 30A) or the second heater line 30 (e.g., 30B, 30C) in the first horizontal direction. In some embodiments, the at least two heater lines may include a third heater line 30 (e.g., 30B, 30C), and the third heater line 30 (e.g., 30B, 30C) may be a different width than the first heater line 30 (e.g., 30A) and the second heater line 30 (e.g., 30B, 30C) in the first horizontal direction. In some embodiments, the at least two heater lines may include a third heater line 30 (e.g., 30B, 30C), and the third heater line 30 (e.g., 30B, 30C) may be a same material as the first heater line 30 (e.g., 30A) or the second heater line 30 (e.g., 30B, 30C). In some embodiments, the at least two heater lines may include a third heater line 30 (e.g., 30B, 30C), and the third heater line 30 (e.g., 30B, 30C) may be a different material than the first heater line 30 (e.g., 30A) and the second heater line 30 (e.g., 30B, 30C).

In some embodiments, the at least two heater lines 30 may include tungsten (W), tungsten titanium (TiW), copper (Cu), aluminum (Al), gold (Au), molybdenum (Mo), or a combination thereof.

According to another aspect of the present disclosure, a switch structure is provided, which comprises: a first electrode 60A; a second electrode 60B; a first heater line 30 (e.g., 30A); a second heater line 30 (e.g., 30B, 30C); and a first phase-change material (PCM) line 40 electrically connecting the first electrode 60A and the second electrode 60B, in which the first PCM line 40 has a channel length in a first horizontal direction hd1 equal to a distance between proximate sidewalls of the first electrode 60A and the second electrode 60B; the first PCM line 40 may be formed over the first heater line 30 (e.g., 30A) wherein a first overlap area between the first heater line 30 (e.g., 30A) and the first PCM line 40 in a plan view is a first PCM cell; and the first PCM line 40—may be formed over the second heater line 30 (e.g., 30B, 30C) wherein a second overlap area between the second heater line 30 (e.g., 30B, 30C) and the first PCM line 40 in a plan view is a second PCM cell, in which a resistance of the first PCM line 40 is a function of the channel length, the first PCM cell, and the second PCM cell.

In some embodiments, the resistance of the first PCM line 40 may be increased if at least one of the first PCM cell and the second PCM cell is activated via a short pulse width signal conveyed across the first heater line 30 (e.g., 30A) and the second heater line 30 (e.g., 30B, 30C) respectively.

In some embodiments, a first end portion of the first PCM line may be contacting a sidewall and a bottom surface of the first electrode 60A, a second end portion of the first PCM line 40 may be contacting a sidewall and a bottom surface of the second electrode 60B, the bottom surface of the first electrode 60A may be in a same vertical plane as the first heater line 30 (e.g., 30A) in a vertical cross-sectional view, and the bottom surface of the second electrode 60B may be in a same vertical plane as the second heater line 30 (e.g., 30B, 30C) in a vertical cross-sectional view.

In some embodiments, the switch structure may further comprise a third electrode 60C; a fourth electrode 60F; and a second PCM line 40B electrically connecting the third electrode 60C and the fourth electrode 60D, in which the second PCM line 40B has a channel length in a first horizontal direction hd1 equal to a distance between proximate sidewalls of the third electrode 60C and the fourth electrode 60D, the second PCM line 40B extends parallelly with respect to the first PCM line 40A, and the second PCM line 40B overlies the first heater line 30 (e.g., 30A) and the second heater line 30 (e.g., 30B, 30C).

The phase-change material devices of the present disclosure may be used as a phase-change material (PCM) switch device, which may provide at least four different resistive states between the first electrode 60A and the second electrode 60B depending on the rate of the cooling rate of the PCM during a programming process and the number of heater lines activated to be in a SET phase. In a first part of a programming process, sufficient electrical current may flow through the heater to raise the temperature of a middle portion of the PCM line 40 close to the melting point of the PCM within the PCM line 40. In a second part of the programming process, the rate of decrease in the electrical current may be selected either to induce crystallization of the PCM in the middle portion of the PCM line 40, or to induce amorphous solidification of the PCM in the middle portion of the PCM line 40. In embodiments in which the middle portion of the PCM line 40 is in a crystalline state, the electrical resistance between the first electrode 60A and the second electrode 60B is in a low state. In embodiments in which the middle portion of the PCM line 40 is in an amorphous state, the electrical resistance between the first electrode 60A and the second electrode 60B is in a high state. In embodiments in which the electrical resistance between the first electrode 60A and the second electrode 60B is in the low state, the PCM switch device of the present disclosure provides an on-state (i.e., a connected state) between the first electrode 60A and the second electrode 60B. In embodiments in which the electrical resistance between the first electrode 60A and the second electrode 60B is in the high state, the PCM switch device of the present disclosure provides an off-state (i.e., a disconnected state) between the first electrode 60A and the second electrode 60B.

The phase-change material switches of the present disclosure may be programmed multiple times into new states as needed. The phase-change material switch of the present disclosure may be used to increase, or decrease, interconnected components that are arranged in a parallel connection. Such interconnected components may comprise capacitors, inductors, diodes, or any other passive or active semiconductor devices. The various phase-change material switches of the present disclosure may be advantageously used to provide versatility in many applications including, but not limited to, radio-frequency (RF) applications, high power applications, consumer applications, and/or for mass storage applications.

The transition between the amorphous state and the crystalline state may be induced by controlling the rate of cooling after application of an electrical pulse that renders the PCM amorphous in a first part of a programming process. The second part of the programming process includes control of the cooling rate of the PCM. In embodiments in which rapid quenching occurs, the PCM may cool into an amorphous high resistivity state. In embodiments in which slow cooling occurs, the PCM may cool into a crystalline low resistivity state.

The PCM switch device of the present disclosure comprises a PCM line 40 that is able to be configured into more than two resistive phases (i.e., more than binary on/off phases). Implementing multiple heater lines with respect to a single PCM line may allow the multiple heater lines to induce an asymmetric temperature gradient across the channel length of the PCM line. By implementing multiple heater lines 30, the resistive states of the PCM line 40 between the electrodes 60 may be greatly customizable, allowing for a PCM switch structure with multiple configurable phases that may be fine-tuned for a variety of applications. For example, a PCM switch structure implementing three heater lines 30 may allow for eight different resistive states to be programmed within the PCM line 40. As another example, a PCM switch structure implementing four heater lines 30 may allow for 16 different resistive states to be programmed within the PCM line 40.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a first electrode;
a second electrode;
a phase-change material (PCM) line in contact with and positioned between the first electrode and the second electrode;
at least two heater lines positioned between the first electrode and the second electrode; and
an isolation layer positioned between the PCM line and the at least two heater lines.

2. The semiconductor structure of claim 1, wherein the at least two heater lines comprise:
a first heater line positioned in a first vertical plane as the PCM line in a vertical cross-sectional view; and
a second heater line positioned in a second vertical plane as the PCM line in the vertical cross-sectional view,
wherein the first heater line and the second heater line are in a same horizontal plane in the vertical cross-sectional view.

3. The semiconductor structure of claim 2, wherein the first heater line is a same width as the second heater line in a first horizontal direction.

4. The semiconductor structure of claim 2, wherein the first heater line is a different width than the second heater line in a first horizontal direction.

5. The semiconductor structure of claim 2, wherein the first heater line is a same material as the second heater line.

6. The semiconductor structure of claim 2, wherein the first heater line is a different material than the second heater line.

7. The semiconductor structure of claims 3 or 4, wherein:
the at least two heater lines further comprise a third heater line, and a width of the third heater line is the same in the first horizontal direction as a first heater line width and a second heater line width.

8. The semiconductor structure of claims 3 or 4, wherein:
the at least two heater lines further comprise a third heater line, and
a width of the third heater line is different in the first horizontal direction than a first heater line width and a second heater line width.

9. The semiconductor structure of claims 5 or 6, wherein:
the at least two heater lines further comprise a third heater line, and
the third heater line is a same material as the first heater line or the second heater line.

10. The semiconductor structure of claims 5 or 6, wherein:
the at least two heater lines further comprise a third heater line, and
the third heater line is a different material than the first heater line and the second heater line.

11. The semiconductor structure of claim 1, wherein the at least two heater lines comprise tungsten (W), tungsten titanium (TiW), copper (Cu), aluminum (Al), gold (Au), molybdenum (Mo), or a combination thereof.

12. A switch structure comprising:
a first electrode;
a second electrode;
a first heater line;
a second heater line; and
a first phase-change material (PCM) line electrically connecting the first electrode and the second electrode, wherein:
the first PCM line has a channel length in a first horizontal direction equal to a distance between proximate sidewalls of the first electrode and the second electrode;
the first PCM line is formed over the first heater line and wherein a first overlap area between the first heater line and the first PCM line in a plan view is a first PCM cell;
the first PCM line is formed over the first second line and wherein a second overlap area between the second heater line and the first PCM line in the plan view is a second PCM cell, and
wherein a resistance of the first PCM line is a function of the channel length, the first PCM cell, and the second PCM cell.

13. The switch structure of claim 12, wherein activation of at least one of the first PCM cell and the second PCM cell via a short pulse width signal conveyed across the first heater line and the second heater line respectively increases the resistance of the PCM line.

14. The switch structure of claim 12, wherein:
a first end portion of the first PCM line contacts a sidewall and a bottom surface of the first electrode,
a second end portion of the first PCM line contacts a sidewall and a bottom surface of the second electrode,
the bottom surface of the first electrode is in a same vertical plane as the first heater line, and
the bottom surface of the second electrode is in a same vertical plane as the second heater line.

15. The switch structure of claim 12, further comprising:
a third electrode;
a fourth electrode; and
a second PCM line electrically connecting the third electrode and the fourth electrode, wherein:
the second PCM line has a channel length in the first horizontal direction equal to a distance between proximate sidewalls of the third electrode and the fourth electrode,
the second PCM line extends in a direction parallel to the first PCM line, and
the second PCM line overlies the first heater line and the second heater line.

16. A method of forming a semiconductor structure, the method comprising:
forming a dielectric isolation layer having a planar top surface over a substrate;
forming at least two heater lines over the planar top surface;
forming at least one heater-capping dielectric plate over the at least two heater lines;
forming a phase-change material (PCM) line over the at least one heater-capping dielectric plate,
forming a first electrode and a second electrode, wherein a first end portion of the PCM line contacts the first electrode and a second end portion of the PCM line contacts the second electrode; and
forming a PCM-capping dielectric plate over the PCM line.

17. The method of claim 16, wherein forming the at least two heater lines over the planar top surface comprises:
forming a first heater line having a first width in a first horizontal direction; and
forming a second heater line having a second width in the first horizontal direction, wherein the first width is different from the second width.

18. The method of claim 16, wherein forming the at least two heater lines over the planar top surface comprises:
forming a first heater line with a first material; and
forming a second heater line with a second material, wherein the first material is different from the second material.

19. The method of claim 16, wherein:
the first end portion of the PCM line contacts a sidewall and a bottom surface of the first electrode,
the second end portion of the PCM line contacts a sidewall and a bottom surface of the second electrode, and
a middle portion of the PCM line between the first end portion and the second end portion overlies the at least two heater lines.

20. The method of claim 16, further comprising:
forming a first dielectric material layer over the PCM-capping dielectric plate;
forming a trench in the first dielectric material layer, wherein a top surface of a horizontally-extending portion of the PCM-capping dielectric plate is exposed;
depositing a conductive material over the first dielectric material layer and in the trench to be in contact with exposed portions of the PCM-capping dielectric plate; and
patterning the conductive material into a trench heater line.
